(19) United States
(12) Patent Application Publication
(10) Pub. No.: US 2007/0281375 A1
(43) Pub. Date: Dec. 6, 2007

(54) MANUFACTURING METHOD OF DISPLAY DEVICE

(75) Inventors: Takahiro IBE, Atsugi (JP); Yosuke SATO, Isehara (JP)

Correspondence Address: FISH & RICHARDSON P.C., P.O. BOX 1022, MINNEAPOLIS, MN, 55440-1022, US

(73) Assignee: SEMICONDUCTOR ENERGY LABORATORY CO., LTD., Atsugi-shi (JP)

(21) Appl. No.: 11/753,700

(22) Filed: May 25, 2007

(30) Foreign Application Priority Data
Jun. 1, 2006 (JP) 2006-153564

(51) Int. Cl. H01L 21/00

(52) U.S. Cl. 438/22

(57) ABSTRACT

A first light-transmitting substrate having a first light-transmitting electrode layer and a second substrate having at least a second electrode layer are attached to each other with a resin which is cured by UV light or the like, to form an inorganic EL light-emitting element. Thus, a display device is manufactured. The light-emitting layer may be interposed between the first light-transmitting substrate having the first electrode layer and the second substrate having the second electrode layer, and may be formed either on the first electrode layer side or on the second electrode layer side.

### BACKGROUND OF THE INVENTION

1. Field of the Invention

The present invention relates to a manufacturing method of a display device.

2. Description of the Related Art

In recent years, a liquid crystal display device and an electroluminescence display device, in which thin film transistors (hereinafter also referred to as TFTs) are formed over a glass substrate in an integrated manner, have been developed. In each of these display devices, a thin film transistor is formed over a glass substrate by using technique for forming a thin film, and a liquid crystal element or a light-emitting element (an electroluminescence element, hereinafter also referred to as an EL element) is formed as a display element over various circuits composed of the thin film transistors so that the device functions as a display device.

Light-emitting elements utilizing electroluminescence are classified depending on whether a light-emitting material is an organic compound or an inorganic compound, and generally, the former are referred to as organic EL elements and the latter are referred to as inorganic EL elements.

Inorganic EL elements are classified into a dispersion type inorganic EL element and a thin film type inorganic EL element depending on its element structure. The dispersion type inorganic EL element has a light-emitting layer in which particles of a light-emitting material are dispersed in a binder, which can be formed by a simple method and has been widely researched.

On the other hand, the thin film type inorganic EL element generally has a structure in which a light-emitting layer is interposed between dielectric layers, and the obtained object is further interposed between electrodes. The dielectric layers and the light-emitting layer are formed by vacuum evaporation by a resistance heating method, an electron beam (EB) method, a sputtering method, or the like. As a phosphor, ZnS to which Cu, Mn, or the like is added is generally used. The amount of an added substance or an element is adjusted depending on desired emission color or the like.

In order to obtain excellent stability, high emission efficiency, and high luminance in the thin film type inorganic EL element manufactured as described above, a method is generally employed, in which heat treatment at high temperature is performed after the light-emitting layer is formed to improve crystallinity. In particular, a thioaluminate based phosphor, which is known as a blue material capable of realizing high luminance and high color purity, or the like can exhibit intrinsic performance by annealing at extremely high temperatures of 500 to 900(° C.) as thermal annealing after the light-emitting layer is formed (for example, Patent Document 1: Japanese Translation of PCT International Application No. 2005-520924). However, in a case where such treatment at high temperature is performed, a substrate with low thermal stability such as a glass substrate cannot be used, and accordingly, a process for manufacturing an element is limited.

### SUMMARY OF THE INVENTION

Thus, it is an object of the present invention to provide an inorganic EL element with high luminance, which is driven over a substrate which cannot withstand high temperature such as a glass substrate. Moreover, it is another object to provide technique for manufacturing a display device which is easier and has higher productivity.

In addition, a display device can be manufactured by using the present invention. Display devices which can use the present invention include a light-emitting display device (also simply referred to as a light-emitting device) in which a thin film transistor (hereinafter also referred to as a TFT) is connected to a light-emitting element in which a layer exhibiting light emission called electroluminescence is interposed between electrodes, and the like. EL elements include an element which at least includes a material, from which electroluminescence can be obtained, and which emits light by making current flow.

One feature of the present invention is that a first light-transmitting substrate having a first light-transmitting electrode layer and a second substrate having at least a second electrode layer are attached to each other with a resin which is cured by UV light or the like, to form an inorganic EL light-emitting element. The light-emitting layer may be interposed between the first light-transmitting substrate having the first electrode layer and the second substrate having the second electrode layer, and may be formed either on the first electrode layer side or on the second electrode layer side. In a case where the light-emitting layer is formed on the first electrode layer side, the light-emitting layer is provided between the first electrode layer and the resin. In a case where the light-emitting layer is formed on the second electrode layer side, the light-emitting layer is provided between the second electrode layer and the resin.

One feature of a manufacturing method of a display device of the present invention includes the steps of forming a first dielectric layer over a first electrode layer formed over a first substrate, forming a light-emitting layer over the first dielectric layer, forming an adhesion layer made of an uncured resin over the light-emitting layer, and curing the adhesion layer after the adhesion layer and a second electrode of a second substrate having a second electrode layer are made in contact with each other, to form a light-emitting element.

Another feature of a manufacturing method of a display device of the present invention includes the steps of forming a first dielectric layer over a first electrode layer formed over a first substrate, forming a light-emitting layer over the first dielectric layer, forming a second dielectric layer over the light-emitting layer, forming an adhesion layer made of an uncured resin over the second dielectric layer, and curing the adhesion layer after the adhesion layer and a second electrode of a second substrate having a second electrode layer are made in contact with each other, to form a light-emitting element.

Another feature of a manufacturing method of a display device of the present invention includes the steps of forming an adhesion layer by attaching a resin having a curing and adhering function, in which particles of a light-emitting material are dispersed, over a first electrode layer formed over a first substrate, and curing the adhesion layer after the adhesion layer and a second electrode of a second substrate having a second electrode layer are made in contact with each other, to form a light-emitting element.

Another feature of a manufacturing method of a display device of the present invention includes the steps of forming, over a first electrode layer formed over a first substrate, a solution including a light-emitting material and a binder by dispersion of the light-emitting material in a solution including the binder; attaching the solution over the first electrode layer, performing baking, and forming a light-emitting layer including the light-emitting material and the binder; forming an adhesion layer by attaching a resin having a curing and adhering function over the light-emitting layer; and curing the adhesion layer after the adhesion layer and a second electrode of a second substrate having a second electrode layer are made in contact with each other, to form a light-emitting element.

The resin having a curing and adhering function may be formed of a simple material such as an epoxy resin, and a high dielectric material or a conductive material may be mixed thereto depending on a case.

By using the present invention, a substrate on which treatment at high temperature is performed and a substrate on which treatment at high temperature is not performed can be separately manufactured and can be finally put together into one display device. Accordingly, an inorganic EL display device with high luminance, which is driven over a substrate on which treatment at high temperature cannot be performed, can be manufactured.

In accordance with the present invention, the first substrate and the second substrate can be separately processed. Therefore, more choices for a manufacturing method of a device are given, leading to improvement in productivity. Further, when a light-emitting material, a high dielectric material, or a conductive material is dispersed in the adhesion layer, the adhesion layer can have a function in addition to an adhering function. Accordingly, a process can be simplified.

### BRIEF DESCRIPTION OF THE DRAWINGS

In the accompanying drawings:

FIGS. 1A to 1C are views each illustrating a manufacturing method of a light-emitting element of the present invention;

FIGS. 2A and 2B are views each illustrating a light-emitting element of the present invention;

FIGS. 3A to 3C are views each illustrating a light-emitting element of the present invention;

FIGS. 4A to 4C are views each illustrating a display device of the present invention;

FIGS. 5A and 5B are views each illustrating a display device of the present invention;

FIGS. 6A and 6B are views each illustrating a display device of the present invention;

FIGS. 7A and 7B are views each illustrating a display device of the present invention;

FIG. 8 is a view illustrating a display device of the present invention;

FIG. 9 is a view illustrating a display device of the present invention;

FIG. 10 is a view illustrating a manufacturing method of a display device of the present invention;

FIG. 11 is a view illustrating a display device of the present invention;

FIGS. 12A and 12B are views each illustrating a display device of the present invention;

FIGS. 13A and 13B are a view and a diagram, respectively, illustrating a display device of the present invention;

FIG. 14 is a view illustrating a display device of the present invention;

FIGS. 15A to 15E are views each illustrating a display device of the present invention;

FIGS. 16A to 16C are views each illustrating a display device of the present invention;

FIGS. 17A and 17B are views each illustrating a display device of the present invention;

FIG. 18 is a diagram illustrating a display device of the present invention;

FIG. 19 is a view illustrating a display device of the present invention;

FIG. 20 is a view illustrating an electronic device of the present invention;

FIGS. 21A to 21C are views each illustrating a lighting device of the present invention;

FIG. 22 is a view illustrating a lighting device of the present invention; and

FIG. 23 is a view illustrating a lighting device of the present invention.

### DETAILED DESCRIPTION OF THE INVENTION

Embodiment Modes of the present invention will be explained below with reference to the drawings. However, the present invention is not limited to explanation to be given below, and it is to be easily understood that various changes and modifications in modes and details thereof will be apparent to those skilled in the art without departing from the purpose and the scope of the present invention. Therefore, the present invention should not be interpreted as being limited to the description of the embodiment modes to be given below. It is to be noted that, in embodiment of the present invention which will be explained below, the same portions or portions having similar functions are denoted by the same reference numerals through different drawings, and the explanation will not be repeated.

### Embodiment Mode 1

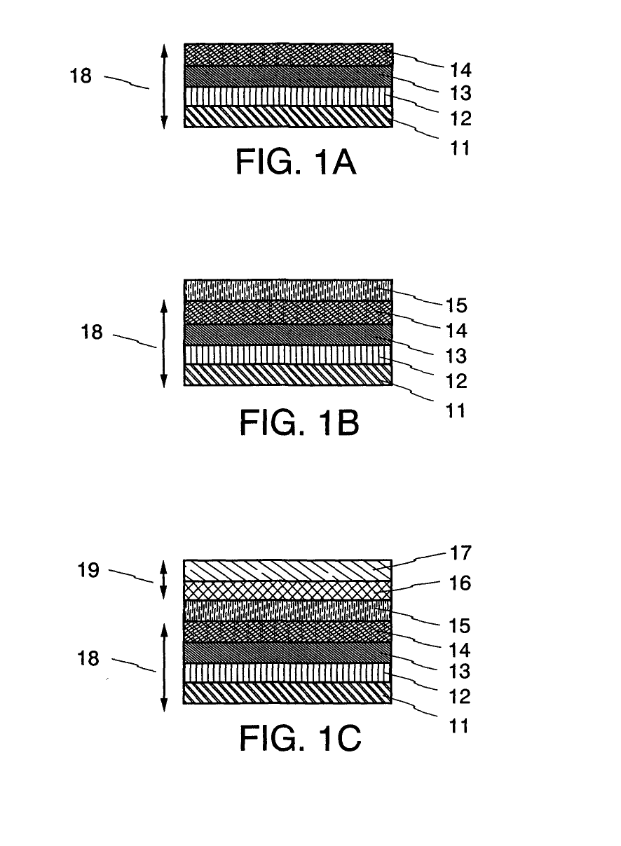

A manufacturing method of a light-emitting element in this embodiment mode will be explained in detail with reference to FIGS. 1A to 1C.

Inorganic EL elements are classified into a dispersion type inorganic EL element and a thin film type inorganic EL element depending on its element structure. They are different from each other in that the former includes a light-emitting layer in which particles of a light-emitting material are dispersed in a binder and the latter includes a light-emitting layer formed of a thin film of a fluorescent material. However, their mechanisms are common, and light emission is obtained through collision excitation of a base material or a luminescent center by electrons accelerated by a high electric field. In this embodiment mode, a manufacturing method of a thin film type inorganic EL element will be explained.

FIGS. 1A to 1C show a manufacturing method of a light-emitting element using the present invention. A structure 18 in FIG. 1A has a first substrate 11, a first electrode 12, a first dielectric layer 13, and a light-emitting layer 14. It is to be noted that the formation of the light-emitting layer 14 includes a step of heat treating a layer which contains the light-emitting material in addition to a step of forming the layer which contains the light-emitting material. The heat treatment step is preferably carried out at 400° C. or more.

As shown in FIG. 1B, an adhesion resin is attached over the light-emitting layer 14 of the structure 18 to form an adhesion layer 15.

Here, as the adhesion resin, a resin cured by energy of light such as UV light or an epoxy resin cured by thermal energy can be used. Besides, a bisphenol-A liquid resin, a bisphenol-A solid resin, a bromine-containing epoxy resin, a bisphenol-F resin, a bisphenol-AD resin, a phenol resin, a cresol resin, a novolac resin, a cycloaliphatic epoxy resin, an Epi-Bis type epoxy resin, a glycidyl ester resin, a glycidyl amine-based resin, a heterocyclic epoxy resin, a modified epoxy resin, or the like can be used. It is to be noted that the adhesion resin is preferably formed to have a thickness greater than or equal to 0.5 μm and less than or equal to 550 μm.

As a method for attaching the adhesion resin, a method such as a dropping method, a dispenser method, a droplet discharge method, a screen printing method, or the like can be used.

This adhesion resin may be formed of a simple material, and a high dielectric material may be mixed therewith as necessary.

Further, a structure 19 having a second electrode 16 and a second substrate 17 is separately prepared, and the second electrode 16 and the adhesion layer 15 are made in contact with each other. After the contact, the adhesion layer 15 is cured.

As a method for curing the adhesion resin to be applied to the present invention, a method such as UV light irradiation or heating can be used according to a kind of the adhesion resin.

Thus, a light-emitting element shown in FIG. 1C can be manufactured. By using the present invention, the structure 18 and the structure 19 can be manufactured through quite different processes. Accordingly, by optimization of conditions of processes through which each structure is manufactured, a high-quality display device can be manufactured.

For example, in a case where treatment at high temperature is performed for the sake of improvement in luminance of the light-emitting layer 14, a quartz substrate, a ceramic substrate, or the like which can withstand heating temperature can be used for the first substrate 11 provided with the light-emitting layer 14, and a glass substrate which is inexpensive and has a high light-transmitting property can be used for the second substrate 17 on which treatment at high temperature is not performed, that is to say, a substrate which has lower heat resistance than the first substrate 11 may be used as the second substrate 17.

Further, the adhesion layer 15 can also have a function of a dielectric layer by mixture with a high dielectric material into the adhesion resin. Accordingly, the number of film formation processes by vacuum evaporation can be reduced, leading to simplification of a process.

### Embodiment Mode 2

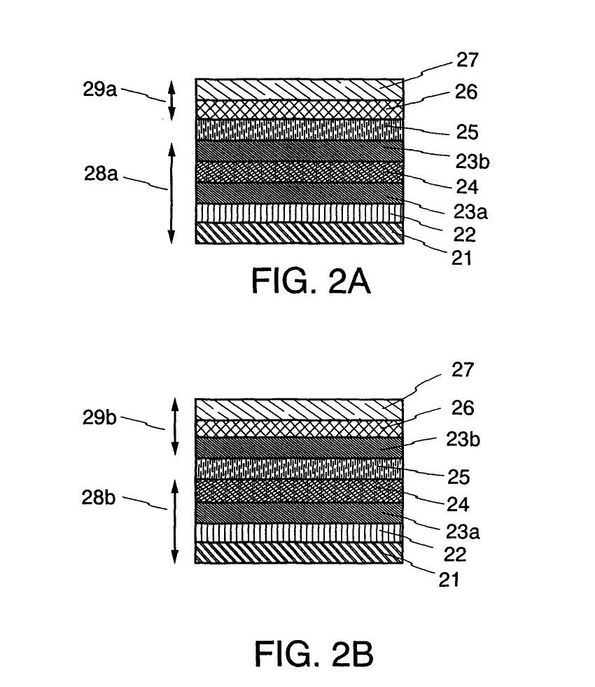

Another structural example of a light-emitting element manufactured using the present invention will be explained with reference to FIGS. 2A and 2B.

A light-emitting material that can be used for a light-emitting layer in the present invention includes a host material and an impurity element to be a light-emitting center. When the contained impurity element is changed, various color emission can be obtained. As a manufacturing method of a light-emitting material, various methods such as a solid phase method and a liquid phase method (a coprecipitation method) can be used. Alternatively, a spraying thermal decomposition method, a double decomposition method, a method by thermal decomposition reaction of a precursor, a reversed micelle method, a method in which these methods and high temperature baking are combined, a liquid phase method such as a freeze-drying method, or the like can be used.

The solid phase method is a method in which a host material and an impurity element are weighed, mixed in a mortar, heated in an electric furnace, and baked to react so as to contain the impurity element in the host material. The baking temperature is preferably 700 to 1500° C. This is because solid-phase reaction does not proceed when temperature is too low, and the host material is decomposed when temperature is too high. The baking may be performed in a powder state; however, it is preferably performed in a pellet state. Baking at a comparatively high temperature is required. However, since it is a simple method, high productivity can be obtained; therefore, it is suitable for mass-production.

The liquid phase method (coprecepitation method) is a method in which a host material and an impurity element are reacted in a solution, dried, and then baked. The particles of the light-emitting material can be dispersed uniformly, and the reaction can be made to proceed even if the particles are small and baking temperature is low.

As a host material used in the present invention, sulfide, oxide, or nitride can be given. As sulfide, for example, zinc sulfide (ZnS), cadmium sulfide (CdS), calcium sulfide (CaS), yttrium sulfide (Y₂S₃), gallium sulfide (Ga₂S₃), strontium sulfide (SrS), barium sulfide (BaS), or the like can be used. As oxide, for example, zinc oxide (ZnO), yttrium oxide (Y₂O₃), or the like can be used. As nitride, for example, aluminum nitride (AlN), gallium nitride (GaN), indium nitride (InN), or the like can be used. Alternatively, zinc selenide (ZnSe), zinc telluride (ZnTe), or the like can be used. Alternatively, a ternary mixed crystal such as calcium sulfide-gallium (CaGa₂S₄), strontium sulfide-gallium (SrGa₂S₄), or barium sulfide-gallium (BaGa₂S₄) can be used.

In the present invention, a light-emitting material contains at least two kinds of impurity element. As a first impurity element, for example, copper (Cu), silver (Ag), gold (Au), platinum (Pt), silicon (Si), or the like can be used. As a second impurity element, for example, fluorine (F), chlorine (Cl), bromine (Br), iodine (I), boron (B), aluminum (Al), gallium (Ga), indium (In), thallium (Tl), or the like can be used.

A light-emitting material including the above material as a host material and only the above first and second impurity elements as the emission center can be used. Such a light-emitting material exhibits light emission due to donor-acceptor recombination.

As an impurity element in a light-emitting material, the first impurity element and a third impurity element may be used so that the light-emitting material contains two kinds of impurity element. As the third impurity element, for example, lithium (Li), sodium (Na), potassium (K), rubidium (Rb), cesium (Cs), nitrogen (N), phosphorus (P), arsenic (As), antimony (Sb), bismuth (Bi), or the like can be used.

As an impurity element in the light-emitting material, further, the third impurity element may be used in addition to the first impurity element and the second impurity element so that the light-emitting material contains three kinds of impurity element. The concentration of these impurity elements may be 0.01 to 10 mol % with respect to the host material, preferably, in the range of 0.1 to 5 mol %.

As an impurity element in the case where solid-phase reaction is utilized, a compound containing the first impurity element and the second impurity element or a compound containing the second impurity element and the third impurity element may be used. In this case, the impurity element is easily diffused and the solid phase reaction easily proceeds; therefore, a uniform light-emitting material can be obtained. In addition, a light-emitting material with high purity can be obtained because an impurity element is not contained excessively. As the compound containing the first impurity element and the second impurity element, for example, copper fluoride (CuF₂), copper chloride (CuCl), copper iodide (CuI), copper bromide (CuBr), copper nitride (Cu₃N), copper phosphide (Cu₃P), silver fluoride (AgF), silver chloride (AgCl), silver iodide (AgI), silver bromide (AgBr), gold chloride (AuCl₃), gold bromide (AuBr₃), platinum chloride (PtCl₂), or the like can be used. As a compound containing the second impurity element and the third impurity element, for example, alkali halide such as lithium fluoride (LiF), lithium chloride (LiCl), lithium iodide (LiI), copper bromide (LiBr), or sodium chloride (NaCl); boron nitride (BN); aluminium nitride (AlN); aluminium antimonide (AlSb); gallium phosphide (GaP); gallium arsenide (GaAs); indium phosphide (InP); indium arsenide (InAs); indium antimonide (InSb); or the like can be used.

In the light-emitting material obtained as described above, light emission due to recombination of a donor-acceptor pair can be obtained, and the light-emitting material has high conductivity. A light-emitting layer using the light-emitting material containing three kinds of impurity element can emit light without requiring hot electrons accelerated by a high electric filed. In other words, it is not necessary to apply high voltage to the light-emitting element; thus, a light-emitting element which can be driven with low drive voltage can be obtained. In addition, since the light-emitting element can emit light with low drive voltage, a light-emitting element with reduced power consumption can be obtained.

Further, in a light-emitting material which does not utilize donor-acceptor recombination, for example, the above material can be used as a host material. In addition, as the emission center, manganese (Mn), copper (Cu), samarium (Sm), terbium (Th), erbium (Er), thulium (Tm), europium (Eu), cerium (Ce), praseodymium (Pr), or the like can be used. Light emission due to such a light-emitting material utilizes an inner-shell electronic transition of a metal ion. It is to be noted that not only metal of a simple material is used as such a light-emitting material, but also a halogen element such as fluorine (F) or chlorine (Cl) may be added for charge compensation.

Each of the light-emitting layers (light-emitting layers 14 and 24) shown in Embodiment Mode 1 and this embodiment mode, respectively, is a layer containing the above light-emitting material, which can be formed by a vacuum evaporation method such as a resistance heating evaporation method or an electron beam evaporation (EB evaporation) method, a physical vapor deposition (PVD) method such as a sputtering method, a chemical vapor deposition (CVD) method such as an organic metal CVD method or a hydride transport low-pressure CVD method, an atomic layer epitaxy method (ALE), or the like.

Although the dielectric layers (dielectric layers 13, and 23a and 23b) shown in Embodiment Mode 1 and this embodiment mode, respectively, are not particularly limited, such a dielectric layer is preferably high in withstand voltage and is dense in film quality, and more preferably high in dielectric constant. For example, silicon oxide (SiO₂), yttrium oxide (Y₂O₃), titanium oxide (TiO₂), aluminum oxide (Al₂O₃), hafnium oxide (HfO₂), tantalum oxide (Ta₂O₅), barium titanate (BaTiO₃), strontium titanate (SrTiO₃), lead titanate (PbTiO₃), silicon nitride (Si₃N₄), zirconium oxide (ZrO₂), or the like, a mixed film thereof, or a stacked films including two or more kinds of these films can be used. These dielectric layers can be formed by sputtering, evaporation, CVD, or the like.

A structure 28a of FIG. 2A is a structure having a first substrate 21, a first electrode 22, a first dielectric layer 23a, a light-emitting layer 24, and a second dielectric layer 23b. An adhesion resin is attached over the second dielectric layer 23b of the structure 28a to form an adhesion layer 25.

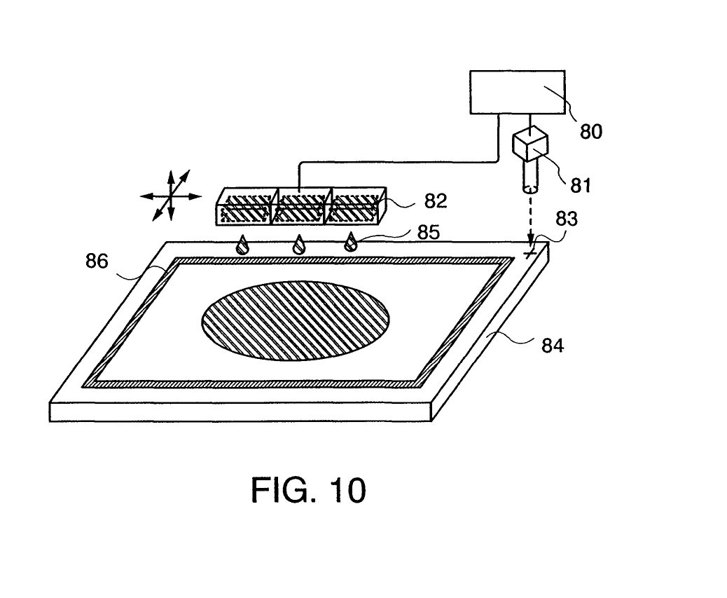

Here, a dropping method is explained as one example of a method for attaching an adhesion resin in the present invention, with reference to FIG. 10. FIG. 10 shows one mode of a drop device of an adhesion resin, which is applicable to the present invention. Reference numeral 80 denotes a dropping control circuit; 81, an imaging unit such as a CCD; 83, a marker; and 82, a head. An adhesion resin is dropped onto a substrate 84 from a nozzle of the dropping head 82 using the dropping control circuit 80. A frame 86 for determining a region of a composition 85 including a liquid adhesion resin is formed on the substrate 84. The composition 85 including the liquid adhesion resin is dropped into a region surrounded by the frame 86, and accordingly, an adhesion layer is formed.

Further, a structure 29a having a second electrode 26 and a second substrate 27 is separately prepared, and the second electrode 26 and the adhesion layer 25 are made in contact with each other. After the contact, the adhesion resin is cured by a method such as UV light irradiation or heating according to a kind of the adhesion resin.

Thus, a light-emitting element shown in FIG. 2A can be manufactured.

Besides, as shown in FIG. 2B, a structure 28b having a first substrate 21, a first electrode 22, a first dielectric layer 23a, and a light-emitting layer 24 and a structure 29b having a second dielectric layer 23b, a second electrode 26, and a second substrate 27 can be adhered to each other with an adhesion layer 25.

As described above, by using the present invention, the structure 28a and the structure 28b, and the structure 28b and the structure 29 can be manufactured through quite different processes. Accordingly, by optimization of processes through which each structure is manufactured, a high-quality display device can be manufactured.

### Embodiment Mode 3

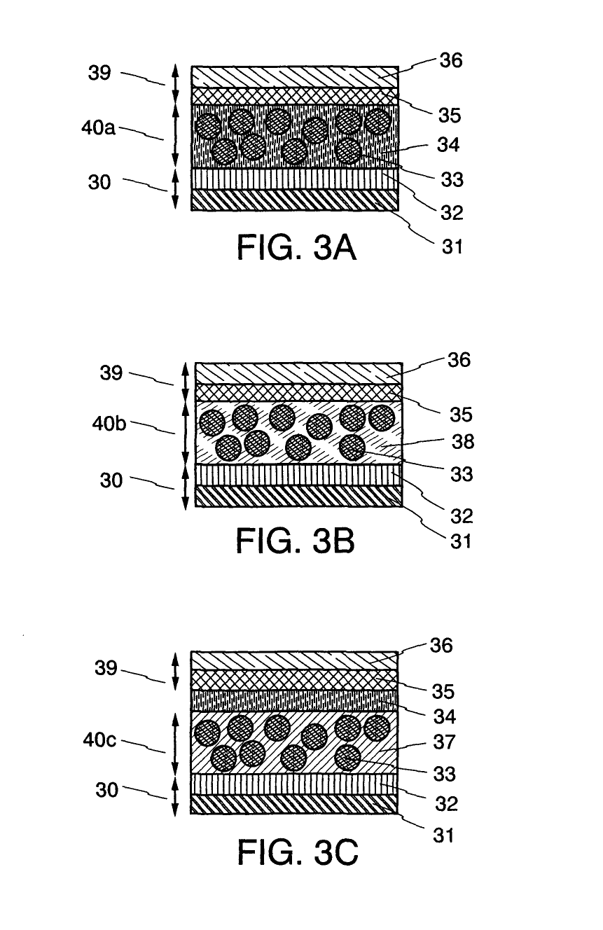

A light-emitting element which can be manufactured using the present invention will be explained with reference to FIGS. 3A to 3C. In this embodiment mode, a manufacturing method of a dispersion type inorganic EL element will be explained.

A structure 30 in FIG. 3A is a structure having a first substrate 31 and a first electrode 32.

An object in which a light-emitting material 33 is dispersed in an adhesion resin 34 is attached over the first electrode 32 of the structure 30 to form an adhesion layer 40a.

As the light-emitting material 33 herein used, the light-emitting material shown in Embodiment Mode 2 is processed into particles. The light-emitting material may be processed by being crushed in a mortar or the like, or through the use of a device such as a mill. When a particle having a sufficiently desired size can be obtained by a manufacturing method of the light-emitting material, further processing may not be performed. The particle diameter may be greater than or equal to 0.1 μm and less than or equal to 50 μm (much preferably, less than or equal to 10 μm). The shape of the light-emitting material may be any shape such as a particle shape, a columnar shape, a needle shape, or a planar shape. Alternatively, particles of a plurality of light-emitting materials may be cohered to be aggregation as a simple material.

Further, a structure 39 having a second electrode 35 and a second substrate 36 is separately prepared, and the second electrode 35 and the adhesion layer 40a are made in contact with each other. After the contact, the adhesion resin is cured by a method such as UV light irradiation or heating according to a kind of the adhesion resin.

Thus, a light-emitting element shown in FIG. 3A can be manufactured. With the use of this method, the adhesion layer can have a function of a light-emitting layer, and a process can be simplified.

Alternatively, as shown in FIG. 3B, an object in which a light-emitting material 33 is dispersed in a material 38 in which an adhesion resin and a high dielectric material are mixed can be used to form an adhesion layer 40b.

Here, an organic material or an inorganic material can be used as a high dielectric material, and further, a mixed material of an organic material and an inorganic material may be used. As the organic material, a polymer having high polarity and a high dielectric constant such as a cyanoethyl cellulose-based resin is preferable. As the inorganic material, a fine particle having a high dielectric constant such as barium titanate (BaTiO₃) or strontium titanate (SrTiO₃) is preferable.

Further alternatively, as shown in FIG. 3C, a light-emitting material 33 is dispersed in a binder 37 formed using a mixture of a high dielectric material and a solvent, the obtained object is attached over a first electrode 32 and dried to form a light-emitting layer 40c, an adhesion resin 34 is attached over the light-emitting layer 40c to form an adhesion layer, and the adhesion layer and a second electrode 35 are made in contact with each other and the adhesion layer is cured. Thus, a light-emitting element can be manufactured.

As the binder that can be used for the present invention, an organic material and an inorganic material can be used. In addition, a mixed material of the organic material and the inorganic material may be used. As the organic material, like a cyanoethyl cellulose-based resin, a polymer having a comparatively high dielectric constant, resin such as polyethylene, polypropylen, a polystyrene-based resin, a silicone resin, an epoxy resin, vinylidene fluoride, or the like can be used. Alternatively, a thermally stable high molecule such as aromatic polyamide and polybenzimidazole, or a siloxane resin may be used. It is to be noted that the siloxane resin corresponds to a resin having a Si—O—Si bond. In siloxane, a skeleton structure is constituted by a bond of silicon (Si) and oxygen (O). As a substituent, an organic group at least including hydrogen (for example, an alkyl group or an aryl group) is used. As the substituent, a fluoro group may be used. Alternatively, an organic group at least including hydrogen and a fluoro group may be used as a substituent. Further alternatively, a resin material such as a vinyl resin like polyvinyl alcohol, polyvinyl butyral, or the like, a phenol resin, a novolac resin, an acrylic resin, a melamine resin, an urethane resin, or an oxazole resin (polybenz oxazole) can be used. Furthermore, a photosensitive resin, for example, the photosensitive resin having a photo-curing property may be used. The dielectric constant can be adjusted by adequately mixing fine particles having a high dielectric constant such as BaTiO₃ or SrTiO₃.

As the inorganic material included in the binder, at least one material selected from silicon oxide, silicon nitride, silicon oxynitride, silicon nitride oxide, aluminum nitride (AlN), aluminum oxynitride (AlON), aluminum nitride oxide (AlNO), or aluminum oxide, titanium oxide (TiO₂), BaTiO₃, SrTiO₃, PbTiO₃, KNbO₃, PbNbO₃, Ta₂O₃, BaTa₂O₆, LiTaO₃, Y₂O₃, Al₂O₃, ZrO₂, ZnS, or other substances including an inorganic insulating material can be used. By including the inorganic material having a high dielectric constant in the organic material (by addition or the like), the dielectric constant of the light-emitting layer formed using the light-emitting material and the binder can be further controlled, and the dielectric constant can be further increased.

As a solvent of a solution that can be used for the binder of the present invention, a solvent in which a binder material is dissolved, and a solution having a viscosity suitable for a method for forming a light-emitting layer (various wet processes) and for a desired film thickness can be formed, may be appropriately selected. In a case where the organic solvent or the like can be used, for example, a siloxane resin is used as a binder, propylene glycol monomethylether, propylene glycol monomethylether acetate (also referred to as PGMEA), 3-methoxy-3-methyl-1-butanol (also referred to as MMB), or the like can be used.

By using the present invention, a substrate on which treatment at high temperature is performed and a substrate on which treatment at high temperature is not performed can be separately manufactured, and finally, a display device of an integration type of this embodiment mode can be manufactured. Accordingly, an inorganic EL display device with high luminance can be manufactured, which is driven over a glass substrate on which treatment at high temperature cannot be performed.

In accordance with the present invention, the first substrate and the second substrate can be separately processed. Therefore, more choices for a manufacturing method of a device are given, leading to improvement in productivity. Further, when a light-emitting material, a high dielectric material, or a conductive material is dispersed in the adhesion layer, the adhesion layer can have a function in addition to an adhering function. Accordingly, a process can be simplified.

### Embodiment Mode 4

In this embodiment mode, a structural example of a display device having a light-emitting element of the present invention will be explained with reference to drawings. More specifically, a passive matrix display device is shown.

Although a thin film type inorganic EL and a dispersion type inorganic EL have different structures, both of the two are the same in terms of performing electroluminescence. Therefore, a portion relating to a light-emitting mechanism of these is referred to as an electroluminescent layer. This electroluminescent layer includes, for example, a light-emitting layer and a dielectric layer in the case of thin film type inorganic EL, or a light-emitting layer formed by baking a material in which particles of a light-emitting material are dispersed in a binder and a dielectric layer in the case of the dispersion type inorganic EL.

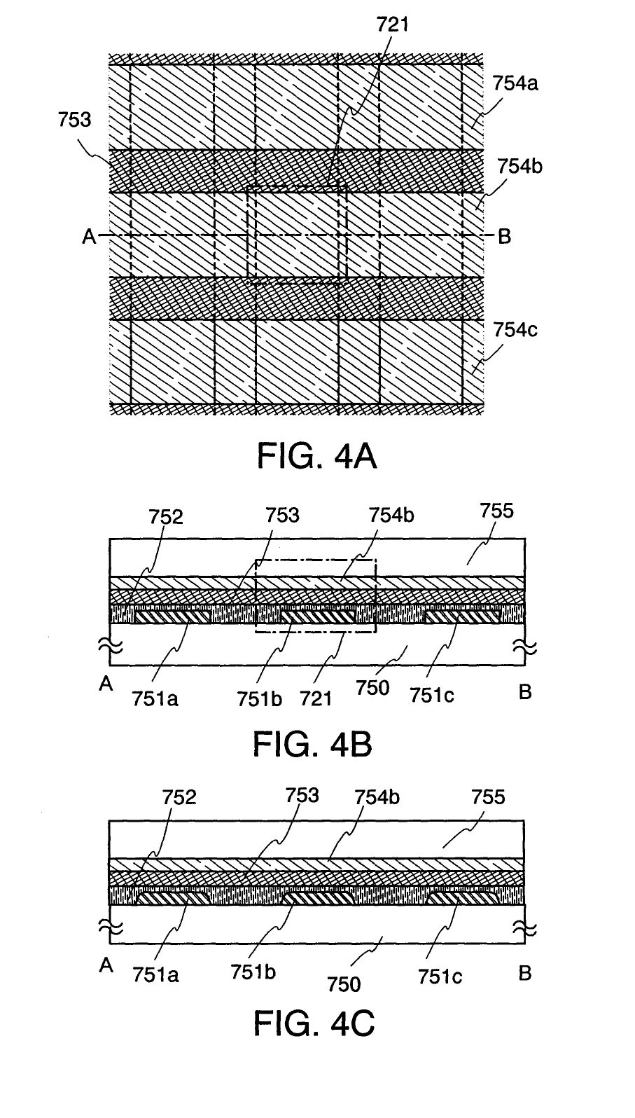

FIG. 4A is a top view of a display device, and FIG. 4B is a cross-sectional view taken along a line A-B in FIG. 4A. Although a second substrate 755 is omitted and not shown in FIG. 4A, it is provided as shown in FIG. 4B.

The display device shown in FIGS. 4A and 4B is provided with a first substrate 750; a first electrode layer 751a, a first electrode layer 751b, and a first electrode layer 751c which are extended in a first direction; an adhesion layer 752 provided to cover the first electrode layer 751a, the first electrode layer 751b, and the first electrode layer 751c; an electroluminescent layer 753; a second electrode layer 754a, a second electrode layer 754b, and a second electrode layer 754c which are extended in a second direction perpendicular to the first direction; and a second substrate 755. The adhesion layer 752 and the electroluminescent layer 753 are provided between the first electrode layer 751a, the first electrode layer 751b, and the first electrode layer 751c, and the second electrode layer 754a, the second electrode layer 754b, and the second electrode layer 754c. The electroluminescent layer 753, the second electrode layer 754a, the second electrode layer 754b, and the second electrode layer 754c are formed over the second substrate. A side of the electrode layer of the first substrate and a side of the electroluminescent layer of the second substrate are adhered to each other with the adhesion layer 752. If there is a concern about influence of an electric field in a lateral direction between adjacent memory cells, the electroluminescent layer 753 provided in each light-emitting element may be separated.

FIG. 4C is an example of deforming the structure shown in FIG. 4B, which has a first substrate 750, a first electrode layer 751a, a first electrode layer 751b, a first electrode layer 751c, an adhesion layer 752, an electroluminescent layer 753, a second electrode layer 754a, a second electrode layer 754b, a second electrode layer 754c, and a second substrate 755. As with the first electrode layer 751a, the first electrode layer 751b, and the first electrode layer 751c shown in FIG. 4C, the first electrode layer may have a tapered shape or a shape in which curvature radius is continuously changed. Such shapes of the first electrode layer 751a, the first electrode layer 751b, and the first electrode layer 751c can be formed by a droplet discharge method or the like. When such a curved surface having a curvature is employed, an advantageous effect of preventing a short-circuit due to electric field concentration at a corner portion of an electrode can be obtained.

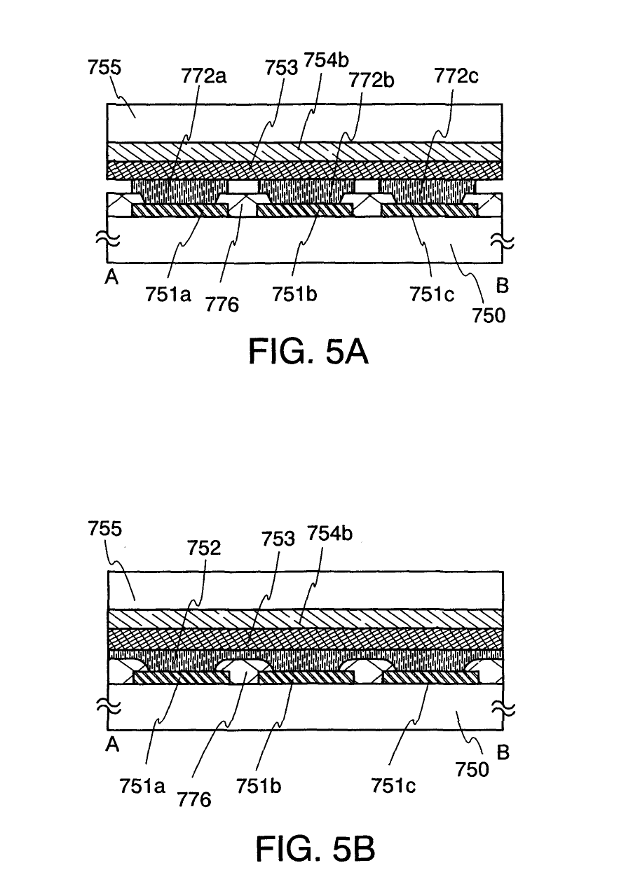

Further, as shown in FIGS. 5A and 5B, a partition wall (insulating layer) may be formed to cover an edge portion of the first electrode layel The partition wall (insulating layer) has a role like a wall partitioning one memory element from another. FIGS. 5A and 5B show the same structure as that in FIGS. 4B and 4C except that the edge portion of the first electrode layer is covered with the partition wall (insulating layer). It is to be noted that FIG. 4A is a top view corresponding to the cross-sectional views shown in FIGS. 5A and 5B.

In an example of a light-emitting element shown in FIG. 5A, a partition wall (insulating layer) 776 serving as a partition wall is formed in a tapered shape so as to cover edge portions of a first electrode layer 751a, a first electrode layer 751b, and a first electrode layer 751c. The partition wall (insulating layer) 776 is formed on the edge portions of the first electrode layer 751a, the first electrode layer 751b, and the first electrode layer 751c provided over a first substrate 750; an adhesion resin is attached over the first electrode layer 751a, the first electrode layer 751b, and the first electrode layer 751c to form a first adhesion layer 772a, a first adhesion layer 772b, and a first adhesion layer 772c, respectively; and a second substrate 755 having an electroluminescent layer 753, a second electrode layer 754a (shown in FIG. 4A), a second electrode layer 754b, and a second electrode layer 754c (shown in FIG. 4A) is made in contact therewith and the adhesion resin is cured. Thus, the light-emitting element is manufactured.

FIG. 5B is an example of deforming the structure shown in FIG. 5A, in which a partition layer (insulating layer) 776 has a curvature, and the curvature is continuously changed. The partition wall (insulating layer) 776 is formed in edge portions of a first electrode layer 751a, a first electrode layer 751b, and a first electrode layer 751c provided over a first substrate 750; an adhesion resin is attached over the first electrode layer 751a, the first electrode layer 751b, and the first electrode layer 751c; and a second substrate 755 having a first adhesion layer 752, an electroluminescent layer 753, a second electrode layer 754a (shown in FIG. 4A), a second electrode layer 754b, and a second electrode layer 754c (shown in FIG. 4A) is in contact therewith and the adhesion resin is cured. Thus, the light-emitting element is manufactured.

The partition wall may have an inverted tapered shape in which an outer edge portion of a top portion protrudes outward with respect to a base portion.

As the first substrate 750 and the second substrate 755, a quartz substrate, a silicon substrate, a metal substrate, a stainless-steel substrate, or the like, in addition to a glass substrate and a flexible substrate, can be used. The flexible substrate is a substrate that can be bent, such as a plastic substrate formed using polycarbonate, polyarylate, polyether sulfone, or the like. In addition, a film (formed using polypropylene, polyester, vinyl, polyvinyl fluoride, vinyl chloride, or the like), paper of a fibrous material, a base film (polyester, polyamide, an inorganic evaporated film, paper, or the like) can be used. Alternatively, the light-emitting element can be provided over a field effect transistor (FET) formed on a semiconductor substrate such as a Si substrate, or over a thin film transistor (TFT) formed over a substrate such as a glass substrate.

A material and a formation method of the first electrode layer, the second electrode layer, the light-emitting material, the light-emitting layer, and the adhesion layer shown in this embodiment mode can be used by employing any of the materials and the methods described in Embodiment Modes 1 to 3.

By using the present invention, a substrate on which treatment at high temperature is performed and a substrate on which treatment at high temperature is not performed can be separately manufactured, and finally, a display device of an integration type of this embodiment mode can be manufactured. Accordingly, an inorganic EL display device with high luminance can be manufactured, which is driven over a glass substrate on which treatment at high temperature cannot be performed.

In accordance with the present invention, the first substrate and the second substrate can be separately processed. Therefore, more choices for a manufacturing method of a device are given, leading to improvement in productivity. Further, when a light-emitting material, a high dielectric material, or a conductive material is dispersed in the adhesion layer, the adhesion layer can have a function in addition to an adhering function. Accordingly, a process can be simplified.

### Embodiment Mode 5

In this embodiment mode, a display device having a structure different from that in Embodiment Mode 4 will be explained. Specifically, a case of an active matrix display device will be shown.

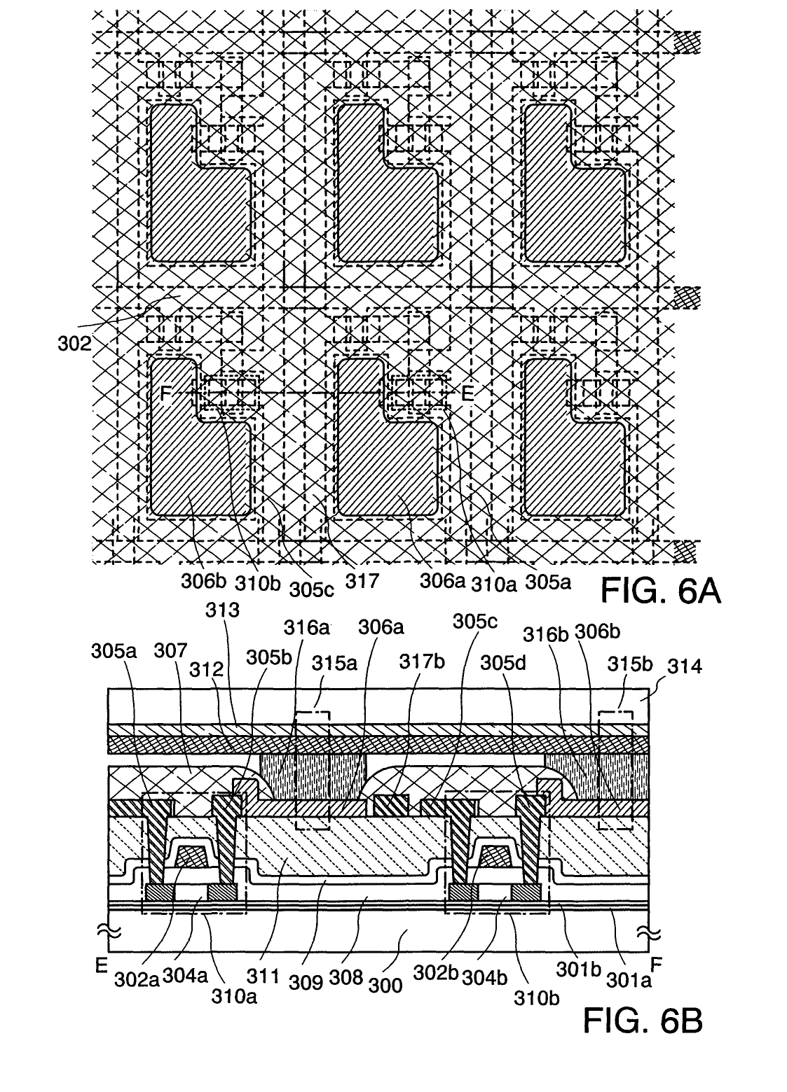

FIG. 6A is a top view of a display device, and FIG. 6B is a cross-sectional view taken along a line E-F in FIG. 6A. Although an electroluminescent layer 312, a second electrode layer 313, and a second substrate 314 are omitted and not shown in FIG. 6A, they are provided as shown in FIG. 6B.

A first wiring extended in a first direction and a second wiring extended in a second direction perpendicular to the first direction are provided in matrix. The first wiring is connected to source electrodes or drain electrodes of a transistor 310a and a transistor 310b, and the second wiring is connected to gate electrodes of the transistor 310a and the transistor 310b. Further, source electrodes or drain electrodes of the transistor 310a and the transistor 310b, which are not connected to the first wiring, are connected to a first electrode layer 306a and a first electrode layer 306b. An adhesion layer 316a and an adhesion layer 316b are formed over the first electrode layer 306a and the first electrode layer 306b, respectively, to be adhered to a second substrate 314 having an electroluminescent layer 312 and a second electrode layer 313. Thus, a light-emitting element 315a and a light-emitting element 315b are formed. A partition layer (insulating layer) 307 is provided between adjacent light-emitting elements and a space is provided over the partition layer 307, thereby preventing direct contact between the partition wall 307 and the electroluminescent layer 312. Further, a thin film transistor is used for the transistor 310a and the transistor 310b (see FIG. 6B).

The light-emitting element of FIG. 6B is provided over a substrate 300, and has an insulating layer 301a; an insulating layer 301b; an insulating layer 308; an insulating layer 309; an insulating layer 311; a semiconductor layer 304a, a gate electrode layer 302a, and a wiring 305a being combined with a function as a source electrode layer or a drain electrode layer included in the transistor 310a; and a semiconductor layer 304b and a gate electrode layer 302b included in the transistor 310b. The adhesion layer 316a and the adhesion layer 316b are formed over the first electrode layer 306a and the first electrode layer 306b, respectively, to be in contact with the second substrate 314 having the electroluminescent layer 312 and the second electrode layer 313. Thus, the light-emitting element is formed.

In a case where a direct current is desired to flow through the electroluminescent layer 312, the adhesion layer 316a and the adhesion layer 316b can have conductivity by mixture of a conductive material into an adhesion resin. As the conductive material, an organic material such as a conductive high molecule may be used, and an inorganic material such as a metal fine particle may be used. For example, a fine particle or a dispersion nanoparticle of metal such as Ag, Au, Cu, Ni, Pt, Pd, Ir, Rh, W, or Al, metal sulfide such as Cd or Zn, an oxide of Fe, Ti, Si, Ge, Zr, Ba, or the like, silver halide, or the like.

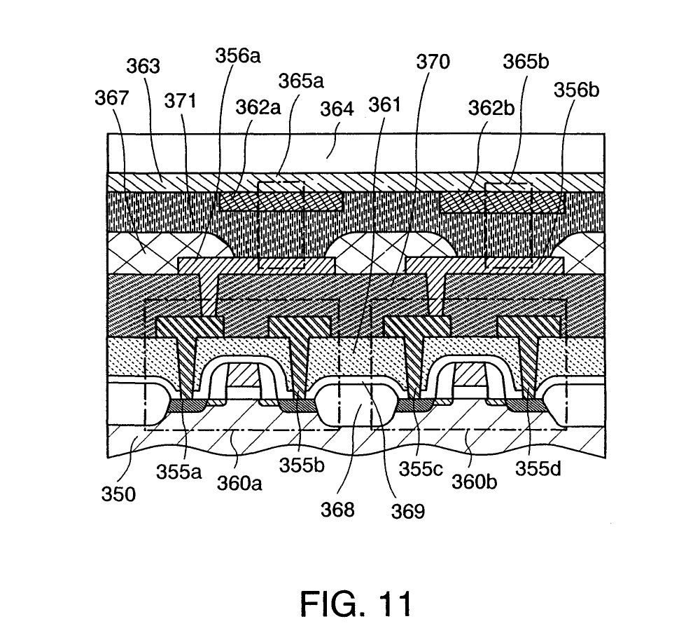

Alternatively, as shown in FIG. 11, a light-emitting element 365a and a light-emitting element 365b may be connected to a field-effect transistor 360a and a field-effect transistor 360b, respectively, provided on a single crystalline semiconductor substrate 350. Here, an insulating layer 370 is provided so as to cover source electrode layers or drain electrode layers 355a to 355d of the field-effect transistor 360a and the field-effect transistor 360b. A first electrode layer 356a, a first electrode layer 356b, and a partition wall (insulating layer) 367 are formed over the insulating layer 370, and the light-emitting element 365a and the light-emitting element 365b are formed thereover using an adhesion layer 371, an electroluminescent layer 362a, an electroluminescent layer 362b, and a second electrode layer 363. Like the electroluminescent layer 362a and the electroluminescent layer 362b, the electroluminescent layer may be selectively provided only in each light-emitting element using a mask or the like. The display device shown in FIG. 11 also has an element isolation region 368, an insulating layer 369, an insulating layer 361, and a second substrate 364. The adhesion layer 371 is formed over the first electrode layer 356a, the first electrode 356b, and the partition wall 367, and the second substrate 364 having the electroluminescent layer 362a, the electroluminescent layer 362b, and the second electrode layer 363 is adhered thereover.

The adhesion layer can be selectively manufactured only in a portion of each light-emitting element as shown in FIG. 6B, or can be continuously manufactured without partitioning light-emitting elements as shown in FIG. 11. In a case where the adhesion layer is manufactured as shown in FIG. 6B, it is preferable to use a droplet discharge method, a screen printing method, a dispenser method, or the like.

In the display device manufactured using the present invention, the first substrate 350 and the second substrate 364 can be manufactured through quite different processes. Accordingly, by optimization of processes through which each substrate is manufactured, a high-quality display device can be manufactured.

When a light-emitting element is formed by being provided with the insulating layer 370 as shown in FIG. 11, a first electrode layer can be freely disposed. In the structure of FIG. 6B, the light-emitting element 315a and the light-emitting element 315b are necessary to be provided in a region avoiding the source electrode layers or the drain electrode layers of the transistor 310a and the transistor 310b. However, with the use of the above-described structure, for example, the light-emitting element 315a and the light-emitting element 315b can be formed above the transistor 310a and the transistor 310b. As a result, the display device manufactured using the present invention can be further integrated.

The transistors 310a and 310b may be provided in any structure as long as they can function as switching elements. Various semiconductors such as an amorphous semiconductor, a crystalline semiconductor, a polycrystalline semiconductor, and a microcrystal semiconductor can be used as a semiconductor layer, and an organic transistor may also be formed by using an organic compound. FIG. 6A shows an example in which a planar type thin film transistor is provided over an insulating substrate; however, a transistor can also be a staggered type or a reverse staggered type.

By using the present invention, a substrate on which treatment at high temperature is performed and a substrate on which treatment at high temperature is not performed can be separately manufactured, and finally, a display device of an integration type of this embodiment mode can be manufactured. Accordingly, an inorganic EL display device with high luminance can be manufactured, which is driven over a glass substrate on which treatment at high temperature cannot be performed.

In accordance with the present invention, the first substrate and the second substrate can be separately processed. Therefore, more choices for a manufacturing method of a device are given, leading to improvement in productivity. Further, when a light-emitting material, a high dielectric material, or a conductive material is dispersed in the adhesion layer, the adhesion layer can have a function in addition to an adhering function. Accordingly, a process can be simplified.

### Embodiment Mode 6

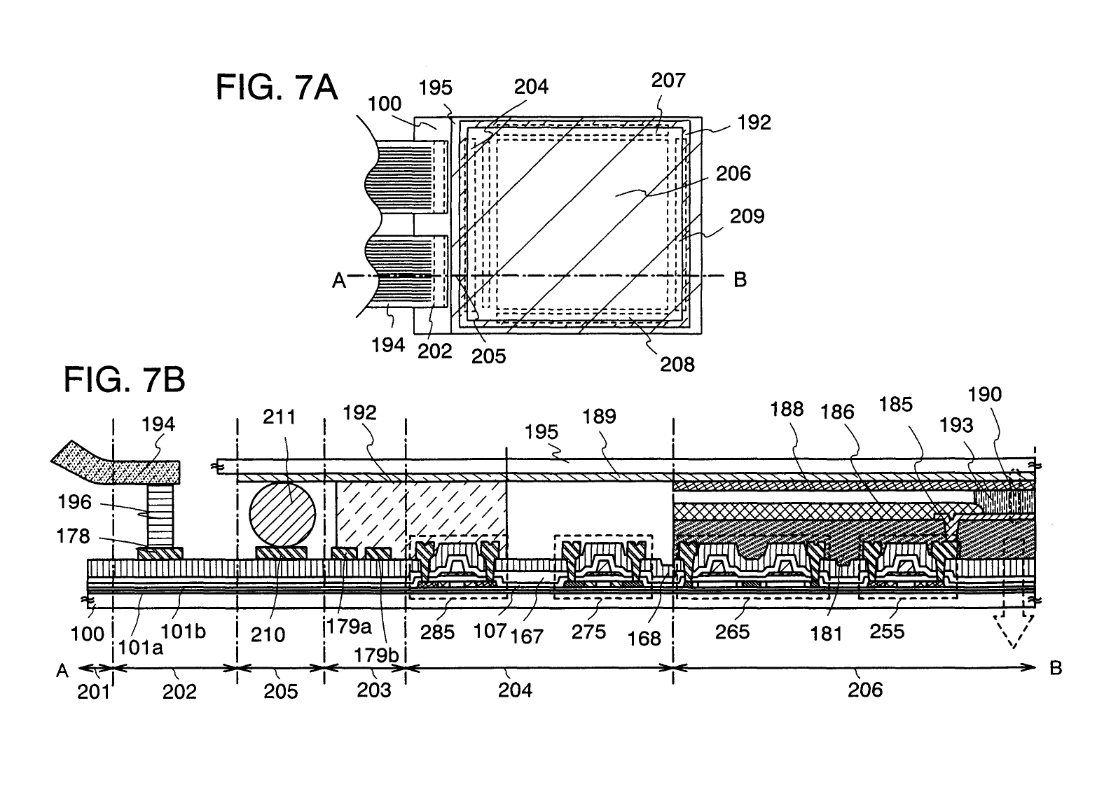

A manufacturing method of a display device in this embodiment mode will be explained with reference to FIGS. 7A and 7B, FIG. 8, FIGS. 16A to 16C, and FIGS. 17A and 17B.

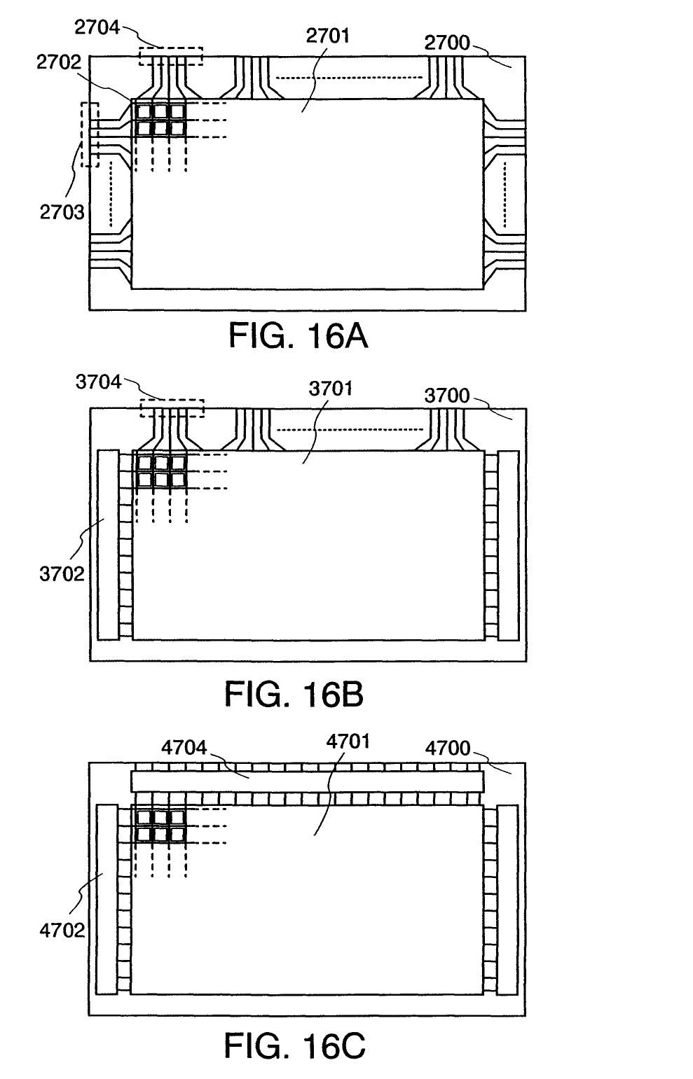

FIG. 16A is a top view showing a structure of a display panel of the present invention, where a pixel portion 2701 in which pixels 2702 are arranged in matrix, a scanning line input terminal 2703, and a signal line input terminal 2704 are formed over a substrate 2700 having an insulating surface. The number of pixels may be provided according to various standards: the number of pixels of XGA for RGB full-color display may be 1024×768×3 (RGB), that of UXGA for RGB full-color display may be 1600×1200×3 (RGB), and that corresponding to a full-spec high-definition display for RGB full-color display may be 1920×1080×3 (RGB).

The pixels 2702 are arranged in matrix by intersecting scanning lines extended from the scanning line input terminal 2703 with signal lines extended from the signal line input terminal 2704. Each pixel 2702 is provided with a switching element and a pixel electrode layer connected to the switching element. A typical example of the switching element is a TFT. A gate electrode layer side of the TFT is connected to the scanning line, and a source or drain side thereof is connected to the signal line, whereby each pixel can be controlled independently by a signal input from outside.

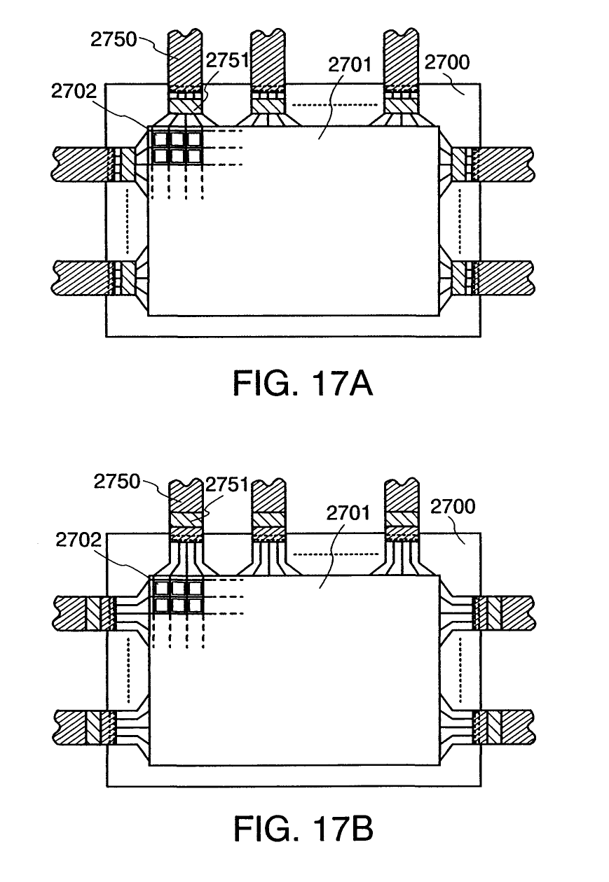

FIG. 16A shows a structure of the display panel in which signals input to a scanning line and a signal line are controlled by an external driver circuit. Alternatively, driver ICs 2751 may be mounted on the substrate 2700 by COG (Chip on Glass) method as shown in FIG. 17A. Further alternatively, the driver ICs may also be mounted by TAB (Tape Automated Bonding) method as shown in FIG. 17B. The driver ICs may be one formed over a single crystalline semiconductor substrate or may be a circuit that is formed using a TFT over a glass substrate. In FIGS. 17A and 17B, each driver IC 2751 is connected to an FPC (Flexible printed circuit) 2750.

Further, in the case where a TFT provided in a pixel is formed using a semiconductor having crystallinity, a scanning line driver circuit 3702 can also be formed over a substrate 3700 as shown in FIG. 16B. In FIG. 16B, a pixel portion 3701 connected to a signal line input terminal 3704 is controlled by an external driver circuit similarly to that in FIG. 16A. In a case where a TFT provided in a pixel is formed using a polycrystalline (microcrystalline) semiconductor, a single crystalline semiconductor, or the like with high mobility, a pixel portion 4701, a scanning line driver circuit 4702, and a signal line driver circuit 4704 can be formed over a substrate 4700 in an integrated manner in FIG. 16C.

In FIGS. 7A and 7B, as base films over a first substrate 100 having an insulating surface, a base film 101a made of a silicon nitride oxide film with a thickness of 10 to 200 nm (preferably, 50 to 150 nm), and a base film 101b made of a silicon oxynitride film with a thickness of 50 to 200 nm (preferably, 100 to 150 nm) are stacked by a sputtering method, a PVD (Physical Vapor Deposition) method, or a CVD (Chemical Vapor Deposition) method such as a low-pressure CVD (LPCVD) method or a plasma CVD method. Alternatively, it is also possible to use acrylic acid; methacrylic acid; derivatives thereof; a thermally stable high molecule such as polyimide, aromatic polyamide, or polybenzimidazole; or a siloxane resin. Further, a resin material can be used such as a vinyl resin (e.g., polyvinyl alcohol or polyvinyl butyral), an epoxy rein, a phenol resin, a novolac resin, an acrylic rein, a melamine resin, or a urethane resin. In addition, it is also possible to use an organic material such as benzocyclobutene, parylene, fluorinated arylene ether, or polyimide, or a composition material containing water-soluble homopolymers and water-soluble copolymers. Further, an oxazole resin such as photo-curing polybenzoxazole can also be used.

Further, a droplet discharge method, a printing method (a method by which patterns are formed such as screen printing or offset printing), a coating method such as spin coating, a dipping method, a dispenser method, or the like can be used. In this embodiment mode, the base film 101a and the base film 101b are formed by a plasma CVD method. As the first substrate 100, a glass substrate, a quartz substrate, a metal substrate, or a stainless steel substrate having an insulating film formed on its surface can be used. Alternatively, a plastic substrate which can withstand the processing temperature in this embodiment mode, or a flexible substrate such as a film can also be used. As a plastic substrate, a substrate made of PET (polyethylene terephthalate), PEN (polyethylene naphthalate), PES (polyethersulfone), or the like can be used. As a flexible substrate, a synthetic resin such as acrylic can be used. A display device manufactured in this embodiment mode has a structure in which light emitted from a light-emitting element is extracted through the first substrate 100, and accordingly, the first substrate 100 needs to have a light-transmitting property.

The base film can be formed using silicon oxide, silicon nitride, silicon oxynitride, silicon nitride oxide, or the like and it may have either a single-layer structure or a stacked structure including two layers, three layers, or the like.

Next, a semiconductor film is formed over the base film. The semiconductor film may be formed with a thickness of 25 to 200 nm (preferably, 30 to 150 nm) by various methods (such as a sputtering method, an LPCVD method, or a plasma CVD method). In this embodiment mode, a crystalline semiconductor film formed by crystallizing an amorphous semiconductor film with a laser beam is preferably used.

As a material for forming the semiconductor film, an amorphous semiconductor (hereinafter also referred to as an “AS”) manufactured by a vapor phase growth method or a sputtering method using a semiconductor material gas typified by silane or germane; a polycrystalline semiconductor that is formed by crystallizing the amorphous semiconductor by utilizing light energy or thermal energy; a semiamorphous (also referred to as microcrystalline or microcrystal) semiconductor (hereinafter also referred to as a “SAS”); or the like can be used.

SAS is a semiconductor having an intermediate structure between amorphous and crystalline (including single crystal and polycrystalline) structures and a third state which is stable in free energy. Moreover, SAS includes a crystalline region with a short range order and lattice distortion. SAS is formed by glow discharge decomposition (plasma CVD) of a gas containing silicon. As the gas containing silicon, SiH₄ can be used, and in addition, Si₂H₆, SiH₂Cl₂, SiHCl₃, SiCl₄, SiF₄ or the like can also be used. Further, F₂ and GeF₄ may be mixed. The gas containing silicon may be diluted with H₂, or H₂ and one or a plurality of rare gas elements of He, Ar, Kr, and Ne. A rare element such as helium, argon, krypton, or neon is made to be contained to promote lattice distortion, thereby favorable SAS with increased stability can be obtained. An SAS layer formed by using a hydrogen-based gas may be stacked over an SAS layer formed by using a fluorine-based gas as the semiconductor film.

Hydrogenated amorphous silicon may be typically given as an example of an amorphous semiconductor, while polysilicon and the like may be typically given as an example of a crystalline semiconductor. Polysilicon (polycrystalline silicon) includes so-called high-temperature polysilicon formed using polysilicon as a main material, which is formed at processing temperatures of 800° C. or higher; so-called low-temperature polysilicon formed using polysilicon as a main material, which is formed at processing temperatures of 600° C. or lower; polysilicon crystallized by addition of an element which promotes crystallization; and the like. It is needless to say that a semi-amorphous semiconductor or a semiconductor containing a crystal phase in part thereof may also be used as described above.

In the case where a crystalline semiconductor film is used for the semiconductor film, the crystalline semiconductor film may be formed by a known method (a laser crystallization method, a thermal crystallization method, a thermal crystallization method using an element such as nickel which promotes crystallization, or the like). Further, a microcrystalline semiconductor that is SAS may be crystallized by laser irradiation, for enhancing crystallinity. In the case where an element which promotes crystallization is not used, before irradiating the amorphous semiconductor film with a laser beam, the amorphous semiconductor film is heated at 500° C. for one hour in a nitrogen atmosphere to discharge hydrogen so that the hydrogen concentration in the amorphous semiconductor film is less than or equal to 1×10²⁰ atoms/cm³. This is because, if the amorphous semiconductor film contains much hydrogen, the amorphous semiconductor film may be broken by laser beam irradiation. Heat treatment for crystallization may be performed with the use of a heating furnace, laser irradiation, irradiation with light emitted from a lamp (also referred to as lamp annealing), or the like. As a heating method, an RTA method such as a GRTA (Gas Rapid Thermal Anneal) method or an LRTA (Lamp Rapid Thermal Anneal) method may be used. A GRTA method is a method in which heat treatment is performed by a high-temperature gas whereas an LRTA method is a method in which heat treatment is performed by light emitted from a lamp.

In a crystallization process in which an amorphous semiconductor layer is crystallized to form a crystalline semiconductor layer, an element which promotes crystallization (also referred to as a catalytic element or a metal element) may be added to an amorphous semiconductor layer, and crystallization may be performed by heat treatment (at 550 to 750° C. for 3 minutes to 24 hours). As a metal element which promotes crystallization of silicon, one or plural kinds selected from metal such as iron (Fe), nickel (Ni), cobalt (Co), ruthenium (Ru), rhodium (Rh), palladium (Pd), osmium (Os), iridium (Ir), platinum (Pt), copper (Cu), and gold (Au) can be used.

A method for introducing a metal element into the amorphous semiconductor film is not particularly limited as long as it is a method which can make the metal element exist on the surface of or inside of the amorphous semiconductor film. For example, a sputtering method, a CVD method, a plasma treatment method (also including a plasma CVD method), an adsorption method, or a method of applying a solution of metal salt can be used. Among them, a method using a solution is simple and advantageous in that the concentration of the metal element can be easily controlled. At this time, it is preferable to form an oxide film by UV light irradiation in an oxygen atmosphere, a thermal oxidation method, a treatment with ozone water containing hydroxyl radical or hydrogen peroxide, or the like so that wettability of the surface of the amorphous semiconductor film is improved, and an aqueous solution is diffused over the entire surface of the amorphous semiconductor film.

In order to remove or reduce the element which promotes crystallization from the crystalline semiconductor layer, a semiconductor layer containing an impurity element is formed to be in contact with the crystalline semiconductor layer and is made to function as a gettering sink. As the impurity element, an impurity element imparting n-type conductivity, an impurity element imparting p-type conductivity, a rare gas element, or the like can be used. For example, one or plural kinds selected from phosphorus (P), nitrogen (N), arsenic (As), antimony (Sb), bismuth (Bi), boron (B), helium (He), neon (Ne), argon (Ar), krypton (Kr), and xenon (Xe) can be used. A semiconductor layer containing a rare gas element is formed over the crystalline semiconductor layer containing the element which promotes crystallization, and heat treatment (at temperatures of 550 to 750° C. for 3 minutes to 24 hours) is performed. The element which promotes crystallization contained in the crystalline semiconductor layer moves into the semiconductor layer containing a rare gas element, and the element which promotes crystallization contained in the crystalline semiconductor layer is removed or reduced. After that, the semiconductor layer containing a rare gas element functioning as the gettering sink is removed.

By scanning a laser beam and the semiconductor film relatively, laser irradiation can be performed. Further, in the laser beam irradiation, beams are made to overlap with each other with high precision or positions for starting and finishing laser beam irradiation is controlled, whereby a marker can be formed. The marker may be formed over the substrate at the same time as the amorphous semiconductor film is formed.

In the case of laser beam irradiation, a continuous wave oscillation type laser beam (a CW laser beam) or a pulsed oscillation type laser beam (a pulsed laser beam) can be used. As a laser beam that can be used here, a laser beam emitted from one or a plurality of kinds of a gas laser such as an Ar laser, a Kr laser, or an excimer laser; a laser using, as a medium, single crystal YAG, YVO₄, forsterite (Mg₂SiO₄), YAlO₃, or GdVO₄, or polycrystal (ceramic) YAG, Y₂O₃, YVO₄, YAlO₃, or GdVO₄ doped with one or a plurality of kinds of Nd, Yb, Cr, Ti, Ho, Er, Tm, and Ta as a dopant; a glass laser; a ruby laser; an alexandrite laser; a Ti: sapphire laser; a copper vapor laser; and a gold vapor laser can be used. By irradiation with the fundamental wave of such a laser beam or the second harmonic to fourth harmonic laser beam of the fundamental wave, a large grain crystal can be obtained. For example, the second harmonic (532 nm) or the third harmonic (355 nm) of an Nd:YVO₄ laser beam (the fundamental wave: 1064 nm) can be used. As for an Nd:YVO₄ laser, either continuous wave oscillation or pulsed oscillation can be performed. In the case of continuous wave oscillation, the power density of the laser beam needs to be approximately 0.01 to 100 MW/cm² (preferably 0.1 to 10 MW/cm²). Then, irradiation is carried out at a scanning rate of approximately 10 to 2000 cm/sec.

Further, a laser using, as a medium, single crystal YAG, YVO₄, forsterite (Mg₂SiO₄), YAlO₃, or GdVO₄, or polycrystal (ceramic) YAG; Y₂O₃, YVO₄, YAlO₃, or GdVO₄ doped with one or a plurality of kinds of Nd, Yb, Cr, Ti, Ho, Er, Tm and Ta as a dopant; an Ar ion laser; or a Ti: sapphire laser can perform continuous wave oscillation. In addition, pulse oscillation at a repetition rate of greater than or equal to 10 MHz is also possible by Q-switch operation, mode locking, or the like. Through pulse oscillation of a laser beam at a repetition rate of greater than or equal to 10 MHz, the semiconductor film is irradiated with the next pulse after the semiconductor film is melted by a laser beam and before the film is solidified. Accordingly, differing from the case where a pulsed laser at a lower repetition rate is used, the solid-liquid interface can be continuously moved in the semiconductor film, and a crystal grain grown continuously in the scanning direction can be obtained.

The use of ceramics (polycrystal) as a medium allows the medium to be formed into a free shape at low cost in a short time. Although a cylindrical columnar medium of several mm in diameter and several tens of mm in length is usually used in the case of single crystal, larger media can be formed in the case of ceramics.

Since the concentration of the dopant such as Nd or Yb in the medium, which directly contributes to light emission, is difficult to be changed significantly both in single crystal and polycrystal, improvement in laser beam output by increasing the concentration of the dopant has a certain level of limitation. However, in the case of ceramics, drastic improvement in output can be expected because the size of the medium can be significantly increased compared with the case of single crystal.

Further, in the case of ceramics, a medium having a parallelepiped shape or a rectangular parallelepiped shape can be easily formed. When a medium having such a shape is used and oscillation light goes in zigzag in the medium, an oscillation light path can be longer. Accordingly, amplification is increased and oscillation with high output is possible. Since a laser beam emitted from the medium having such a shape has a cross section of a quadrangular shape when being emitted, a linear beam can be easily shaped compared with the case of a circular beam. The laser beam emitted in such a manner is shaped by using an optical system; accordingly, a linear beam having a short side of less than or equal to 1 mm and a long side of several mm to several m can be easily obtained. In addition, by uniformly irradiating the medium with excited light, a linear beam has a uniform energy distribution in a long side direction. Further, the semiconductor film may be irradiated with a laser beam at an incident angle θ (0<θ<90°) with respect to the semiconductor film, thereby an interference of the laser beam can be prevented.

By irradiation to the semiconductor film with this linear beam, the entire surface of the semiconductor film can be annealed more uniformly. In the case where uniform annealing is required from one end to the other end of the linear beam, slits may be provided for the both ends so as to shield a portion where energy is attenuated.

When the thus obtained linear beam with uniform intensity is used to anneal the semiconductor film and this semiconductor film is used to manufacture a display device, the display device has favorable and uniform characteristics.

The semiconductor film may be irradiated with a laser beam in an inert gas atmosphere such as a rare gas or nitrogen as well. Accordingly, roughness of the surface of the semiconductor film can be prevented by laser beam irradiation, and variation of threshold voltage due to variation of interface state density can be prevented.

The amorphous semiconductor film may be crystallized by a combination of heat treatment and laser beam irradiation, or either of heat treatment or laser beam irradiation may be performed a plurality of times.

In this embodiment mode, the amorphous semiconductor film is formed over the base film 101b, and the amorphous semiconductor film is crystallized; thus, a crystalline semiconductor film is formed.

After removing an oxide film formed over the amorphous semiconductor film, an oxide film is formed with a thickness of 1 to 5 nm by UV light irradiation in an oxygen atmosphere, a thermal oxidization method, treatment with ozone water or hydrogen peroxide including hydroxyl radical, or the like. In this embodiment mode, Ni is used as an element which promotes crystallization. An aqueous solution containing 10 ppm of Ni acetate is applied by a spin coating method.

In this embodiment mode, after performing thermal treatment at 750° C. for 3 minutes by an RTA method, the oxide film formed over the semiconductor film is removed and laser light irradiation is applied. The amorphous semiconductor film is crystallized by the aforementioned crystallization treatment to be a crystalline semiconductor film.

In the case of performing crystallization using a metal element, a gettering step is performed for reducing or removing the metal element. In this embodiment mode, the metal element is captured using the amorphous semiconductor film as a gettering sink. First, an oxide film is formed over the crystalline semiconductor film by UV light irradiation in an oxygen atmosphere, a thermal oxidation method, treatment with ozone water or hydrogen peroxide including hydroxyl radical, or the like. It is desirable that the oxide film be formed thicker by heat treatment. Subsequently, an amorphous semiconductor film is formed with a thickness of 50 nm by a plasma CVD method (with a condition of this embodiment mode as 350 W, 35 Pa, deposition gas: SiH₄ (flow rate of 5 sccm) and Ar (flow rate 1000 sccm)).

After that, thermal treatment is performed at 744° C. for three minutes by an RTA method to reduce or remove the metal element. The thermal treatment may be performed in a nitrogen atmosphere. Then, the amorphous semiconductor film as a gettering sink and an oxide film formed over the amorphous semiconductor film are removed with hydrofluoric acid and the like, thereby a crystalline semiconductor film in which the metal element is reduced or removed can be obtained. In this embodiment mode, the amorphous semiconductor film as a gettering sink is removed using TMAH (Tetramethyl ammonium hydroxide).

The semiconductor film obtained in this manner may be doped with a slight amount of an impurity element (boron or phosphorus) for controlling a threshold voltage of a thin film transistor. This doping of an impurity element may be performed on an amorphous semiconductor film before a crystallization step. When an impurity element is doped in a state of the amorphous semiconductor film, the impurity can be activated by heat treatment for crystallization later. Further, a defect and the like generated at the doping can be improved as well.

Subsequently, the crystalline semiconductor film is processed into a desired shape, and thus a semiconductor layer is formed.

An etching process may adopt either plasma etching (dry etching) or wet etching. However, in the case of processing a large area substrate, plasma etching is suitable. As an etching gas, a fluorine-based gas such as CF₄ and NF₃ or a chlorine-based gas such as Cl₂ and BCl₃ is used, to which an inert gas such as He and Ar may be appropriately added. Further, in the case of applying an etching process by atmospheric pressure discharge, local discharge can be realized, thereby a mask layer is not required to be formed over an entire surface of the substrate.

In the present invention, a conductive layer for forming a wiring layer or an electrode layer, a mask layer for forming a predetermined pattern, or the like may be formed by a method where a pattern can be selectively formed such as a droplet discharge method. In the droplet discharge (ejection) method (also referred to as an inkjet method depending on the system thereof), a predetermined pattern (a conductive layer, an insulating layer, and the like) can be formed by selectively discharging (ejection) droplets of a composition prepared for a specific purpose. At this time, a process for controlling wettability and adhesion may be performed on a region for forming a pattern. Additionally, a method for transferring or drawing a pattern, for example, a printing method (a method for forming a pattern such as screen printing and offset printing) or the like can be used.

In this embodiment mode, a resin material such as an epoxy resin, an acrylic resin, a phenol resin, a novolac resin, a melamine resin, or a urethane resin is used for a mask to be used. Alternatively, the mask may be formed using an organic material such as benzocyclobutene, parylene, fluorinated arylene ether and polyimide having a light transmitting property; a compound material formed by polymerization of siloxane-based polymers or the like; a composition material containing a water-soluble homopolymer and a water-soluble copolymer; and the like. In addition, a commercially available resist material containing a photosensitive agent may also be used. For example, a novolac resin and a naphthoquinonediazide compound that is a photosensitive agent, which are typical positive type resist; a base resin that is a negative type resist, diphenylsilanediol, an acid generating material, and the like may be used. In the case where a droplet discharge method is used, even when any material is used, the surface tension and the viscosity are appropriately controlled by adjusting the solvent concentration or by adding a surfactant or the like.

The gate insulating layer 107 covering the semiconductor layer is formed. The gate insulating layer is formed of an insulating film containing silicon with a thickness of 10 to 150 nm using a plasma CVD method, a sputtering method, or the like. The gate insulating layer may be formed of a known material such as an oxide material or nitride material of silicon, typified by silicon nitride, silicon oxide, silicon oxynitride, and silicon nitride oxide and may be stacked layers or a single layer. Three stacked layers of a silicon nitride film, a silicon oxide film, and a silicon nitride film are used for the gate insulating layer. Alternatively, the gate insulating layer may be stacked layers of three layers of a silicon nitride film, a silicon oxide film, and a silicon nitride film, or a single layer or stacked layers of two layers of a silicon oxynitride film.

Then, a gate electrode layer is formed over the gate insulating layer 107. The gate electrode layer can be formed by a known method such as a sputtering method, an evaporation method, or a CVD method. The gate electrode layer may be formed of an element selected from tantalum (Ta), tungsten (W), titanium (Ti), molybdenum (Mo), aluminum (Al), copper (Cu), chromium (Cr), and neodymium (Nd), or an alloy material or compound material having the aforementioned element as a main component. Moreover, a semiconductor film typified by a polycrystalline silicon film which is doped with an impurity element such as phosphorus or an AgPdCu alloy may be used. The gate electrode layer may be formed into a single layer or a stacked layer.

In this embodiment mode, the gate electrode layer is formed to have a tapered shape. However, the present invention is not limited to this and only one side of the gate electrode layer may have a tapered shape while the other side may have a perpendicular side surface by anisotropic etching. As described in this embodiment mode, a taper angle may be different or the same between the stacked gate electrode layers. With the tapered shape, coverage by a film stacked thereover is improved and defects are reduced, which improves reliability.

The gate insulating layer 107 is etched to some degree by the etching step of forming the gate electrode layer and a thickness thereof is reduced (what is called film reduction) in some cases.

An impurity region is formed by addition of an impurity element to the semiconductor layer. The impurity regions can be a high concentration impurity region and a low concentration impurity region by control of the concentration. A structure of a thin film transistor having the low concentration impurity region is referred to as an LDD (Light doped drain) structure. The low concentration impurity region can be formed so as to be overlapped with a gate electrode, and a structure of such a thin film transistor is referred to as a GOLD (Gate overlapped LDD) structure. The polarity of the thin film transistor is made to be n-type by phosphorous (P) or the like being used for the impurity region. In a case where the polarity of the thin film transistor is made to be p-type, boron (B) or the like may be added.

In this embodiment mode, an impurity region overlapped with a gate electrode layer with a gate insulating layer interposed therebetween is expressed as a Lov region while an impurity region which is not overlapped with a gate electrode layer with a gate insulating layer interposed therebetween is expressed as a Loff region. In FIGS. 7A and 7B, the impurity regions are expressed by hatching and white, which does not mean that an impurity element is not added to the white portion. They are expressed like this so that it is intuitively recognized that the concentration distribution of impurity elements in this region reflects the mask and the doping condition. It is to be noted that this is similar in the other drawings of this specification.

In order to activate an impurity element, heat treatment or irradiation of intense light or laser light may be carried out. At the same time as the activation, plasma damage to the gate insulating layer or an interface between the gate insulating layer and the semiconductor layer can be improved.

Then, a first interlayer insulating layer covering the gate electrode layers and the gate insulating layer is formed. In this embodiment mode, the first interlayer insulating layer has a stacked structure of insulating films 167 and 168. The insulating films 167 and 168 can be formed of a silicon nitride film, a silicon nitride oxide film, a silicon oxynitride film, a silicon oxide film, or the like by a sputtering method or a plasma CVD method, or a single layer or a stacked structure of three or more layers of other insulating films containing silicon.

Further, thermal treatment is performed at 300 to 550° C. for 1 to 12 hours in a nitrogen atmosphere to hydrogenate the semiconductor layer. The temperature is preferably 400 to 500° C. This step is carried out for terminating dangling bonds in the semiconductor layer by hydrogen contained in the insulating film 167 which is an interlayer insulating layer. In this embodiment mode, the thermal treatment is carried out at 410° C.

Alternatively, the insulating films 167 and 168 can be formed using at least one material selected from aluminum nitride (AlN), aluminum oxynitride (AlON), aluminum nitride oxide (AlNO) containing more nitrogen than oxygen, aluminum oxide, diamond-like carbon (DLC), nitrogen-containing carbon (CN), polysilazane, or other substances including an inorganic insulating material. Alternatively, a material containing siloxane may be used. Further, an organic insulating material may be used, such as polyimide, acrylic, polyamide, polyimide amide, resist, or benzocyclobutene. Moreover, an oxazole resin can also be used, which is, for example, photo-curing polybenzoxazole.

Next, contact holes (openings) reaching the semiconductor layer are formed in the insulating films 167 and 168, and the gate insulating layer 107 by using a mask made of resist. A conductive film is formed so as to cover the openings, and the conductive film is etched to form source electrode layers or drain electrode layers which are electrically connected to portions of respective source regions or drain regions. The source electrode layers and drain electrode layers can be formed by depositing conductive films by a PVD method, a CVD method, an evaporation method, or the like and then etching them into desired shapes. Furthermore, a conductive layer can be selectively formed at a predetermined position by a droplet discharge method, a printing method, a dispenser method, an electrolytic plating method, or the like. In addition, a reflow method, a damascene method, or the like may also be employed. The source electrode layers or drain electrode layers are formed of a metal such as Ag, Au, Cu, Ni, Pt, Pd, Ir, Rh, W, Al, Ta, Mo, Cd, Zn, Fe, Ti, Si, Ge, Zr, or Ba, an alloy or a metal nitride thereof. A stacked structure of the aforementioned substances may also be used.

By the aforementioned steps, an active matrix substrate can be formed, which includes a p-channel thin film transistor 285 having a p-type impurity region in a Lov region and an n-channel thin film transistor 275 having an n-type impurity region in a Lov region in a peripheral driver circuit region 204, a multi-channel type n-channel thin film transistor 265 having an n-type impurity region in a Loff region and a p-channel thin film transistor 255 having a p-type impurity region in a Lov region in a pixel region 206.

The structure of the thin film transistor is not limited to that shown in this embodiment mode, and may be a single gate structure having one channel forming region, a double gate structure having two channel forming regions, or a triple gate structure having three channel forming regions. Moreover, a thin film transistor in the peripheral driver circuit region may have a single gate structure, a double gate structure, or a triple gate structure.

Next, an insulating film 181 is formed as a second interlayer insulating layer. FIGS. 7A and 7B include a separating region 201 for separating the substrate by scribing, an external terminal connection region 202 as an attaching portion of an FPC, a connection region 205 by which a second electrode layer 189 over a second substrate 195 and a connection wiring 210 over a first substrate are attached to each other, a wiring region 203 as a peripheral leading wiring region, a peripheral driver circuit region 204, and a pixel region 206. The connection region 205 is provided with a conductive filler 211 for electrically attaching the connection wiring 210 and the second electrode layer 189 to each other. The wiring region 203 is provided with wirings 179a and 179b and the external terminal connection region 202 is provided with a terminal electrode layer 178 connected to an external terminal.

The insulating film 181 can be formed using at least one material selected from silicon oxide, silicon nitride, silicon oxynitride, silicon nitride oxide, aluminum nitride (AlN), aluminum oxynitride (AlON), aluminum nitride oxide (AlNO) containing oxygen, aluminum oxide, diamond-like carbon (DLC), a nitrogen-containing carbon film (CN), PSG (phosphosilicate glass), BPSG (borophosphosilicate glass), an alumina film, or other substances including an inorganic insulating material. Alternatively, a siloxane resin may also be used. Further, an organic insulating material may be used, which may be a photosensitive type or a non-photosensitive type, such as polyimide, acrylic, polyamide, polyimide amide, resist, benzocyclobutene, polysilazane, or a low dielectric constant (Low-k) material. Moreover, an oxazole resin can also be used, which is, for example, photo-curing polybenzoxazole. An interlayer insulating layer provided for planarization is required to be high in thermal stability, an insulating property, and a planarizing property. Therefore, a coating method typified by a spin coating method is preferably used for forming the insulating film 181.

The insulating film 181 can be formed by a dipping method, spray coating, a doctor knife, a roll coater, a curtain coater, a knife coater, a CVD method, an evaporation method, or the like. The insulating film 181 may be formed by a droplet discharge method. In the case of using a droplet discharge method, a material solution can be used economically. Moreover, a method enabling a pattern to be transferred or drawn such as a droplet discharge method, for example, a printing method (a method to form a pattern such as screen printing or offset printing) can also be used.

A minute opening, that is, a contact hole is formed in the insulating film 181 in the pixel region 206.

Next, a first electrode layer 185 (also called a pixel electrode layer) is formed so as to be in contact with the source electrode layer or the drain electrode layer. The first electrode layer 185 functions as an anode or a cathode and may be formed of a film containing as a main component an element selected from Ti, Ni, W, Cr, Pt, Zn, Sn, In, or Mo, an alloy material or a compound material containing the aforementioned element as a main component, such as titanium nitride, TiSi_{X}N_{Y}, WSi_{X}, tungsten nitride, WSi_{X}N_{Y}, and NbN, or a stacked film of these with a total thickness of 100 to 800 nm.

In this embodiment mode, a light-emitting element is used as a display element and light emitted from the light-emitting element is extracted from the first electrode layer 185 side. Therefore, the first electrode layer 185 has a light-transmitting property. As the first electrode layer 185, a transparent conductive film is formed and etched into a desired shape.

In the present invention, a transparent conductive film formed of a conductive material having a light-transmitting property is preferably used in the first electrode layer 185 as a light-transmitting electrode layer, for which indium oxide containing tungsten oxide, indium zinc oxide containing tungsten oxide, indium oxide containing titanium oxide, indium tin oxide containing titanium oxide, or the like can be used. It is needless to say that indium tin oxide (ITO), indium zinc oxide (IZO), indium tin oxide to which silicon oxide is added (ITSO), or the like can also be used.

Further, when a material such as a metal film having no light-transmitting property is formed thin (preferably a thickness of about 5 to 30 nm) so as to be able to transmit light, light can be emitted through the first electrode 185. As a metal thin film which can be used for the first electrode layer 185, a conductive film formed of titanium, tungsten, nickel, gold, platinum, silver, aluminum, magnesium, calcium, lithium, or an alloy thereof, or the like can be used.

The first electrode layer 185 can be formed by an evaporation method, a sputtering method, a CVD method, a printing method, a dispenser method, a droplet discharge method, or the like. In this embodiment mode, the first electrode layer 185 is formed of indium zinc oxide containing tungsten oxide by a sputtering method. The first electrode layer 185 is preferably formed with a total thickness of 100 to 800 nm.

The first electrode layer 185 may be cleaned by a polyvinyl alcohol-based porous body or polished by a CMP method so as to planarize the surface. Moreover, after polishing the first electrode layer by a CMP method, UV light irradiation or oxygen plasma treatment may be applied to the surface of the first electrode layer 185.

After forming the first electrode layer 185, heat treatment may be performed. By this heat treatment, moisture contained in the first electrode layer 185 is discharged. Therefore, since the first electrode layer 185 does not generate degasification or the like, even when a light-emitting material which is easily deteriorated due to moisture is formed over the first electrode layer, the light-emitting material is not deteriorated. As a result, a highly reliable display device can be manufactured.

Next, an insulating layer 186 (called a partition, a barrier, a bank, or the like) is formed to cover an edge portion of the first electrode layer 185 and the source electrode layer or the drain electrode layer.

As the insulating layer 186, silicon oxide, silicon nitride, silicon oxynitride, silicon nitride oxide, or the like can be used, and a single layer or a stacked structure including two layers, three layers, or the like may be used. In addition, as another material of the insulating layer 186, at least one material selected from aluminum nitride, aluminum oxynitride in which the content of oxygen is higher than that of nitrogen, aluminum nitride oxide or aluminum oxide in which the content of nitrogen is higher than that of oxygen, diamond-like carbon (DLC), nitrogen-containing carbon, polysilazane, or other substances including an inorganic insulating material can be used. A material containing siloxane may also be used. Further, an organic insulating material may be used, which may be a photosensitive type or a non-photosensitive type, such as polyimide, acrylic, polyamide, polyimide amide, resist, benzocyclobutene, or polysilazane. Moreover, an oxazole resin can also be used, which is, for example, photo-curing polybenzoxazole.

The insulating layer 186 can be formed by a sputtering method, a PVD (Physical Vapor Deposition) method, a low pressure CVD method (LPCVD method), or a CVD method (Chemical Vapor Deposition) such as a plasma CVD method. Alternatively, a droplet discharge method by which a pattern can be selectively formed, a printing method by which a pattern can be transferred or described (a method, such as a screen printing method or an offset printing method, by which a pattern is formed), or other methods such as a coating method such as a spin coating method, a dipping method, a dispenser method, or the like can also be used.

An etching process for processing into a desired shape may employ either plasma etching (dry etching) or wet etching. In a case of processing a large area substrate, plasma etching is suitable. As an etching gas, a fluorine-based gas such as CF₄ or NF₃ or a chlorine-based gas such as Cl₂ or BCl₃ is used, to which an inert gas such as He or Ar may be appropriately added. When an etching process by atmospheric pressure discharge is employed, local electric discharge can also be realized, which does not require a mask layer to be formed over an entire surface of the substrate.

An adhesion resin is attached over the first electrode layer 185 to form an adhesion layer 193. Further, the conductive filler 211 is attached over the connection wiring 210 in the connection region 205.

Here, the adhesion layer 193 can have conductivity by mixture of a conductive material into an adhesion resin. As the conductive material, an organic material such as a conductive high molecule may be used, and an inorganic material such as a metal fine particle may be used. For example, a fine particle or a dispersed nanoparticle of metal such as Ag, Au, Cu, Ni, Pt, Pd, Ir, Rh, W, or Al, metal sulfide such as Cd or Zn, an oxide of Fe, Ti, Si, Ge, Zr, Ba, or the like, silver halide, or the like.

Besides, a sealing material 192 for firmly fixing the first substrate 100 to the second substrate 195 may be prepared as shown in FIGS. 7A and 7B. In that case, as the sealing material 192, it is preferable to typically use a visible light curing, UV curing, or thermosetting resin is preferably used. For example, an epoxy resin such as a bisphenol-A type liquid resin, a bisphenol-A type solid resin, a bromine-containing epoxy resin, a bisphenol-F type resin, a bisphenol-AD type resin, a phenol resin, a cresol resin, a novolac resin, a cyclic aliphatic epoxy resin, an epi-bis epoxy resin, a glycidyl ester-based resin, a glycidyl amine-based resin, a heterocyclic epoxy resin, or a modified epoxy resin can be used.

Then, an object is separately prepared, in which the second electrode layer 189 is formed over the second substrate 195 and an electroluminescent layer 188 is formed over the second electrode layer 189. Although only one pixel is illustrated in FIGS. 7A and 7B, in this embodiment mode, electric-field electrode layers corresponding to each color of R (red), G (green), and B (blue) are separately formed. The electroluminescent layer 188 may be manufactured as shown in Embodiment Mode 1.

As the second electrode layer 189, Al, Ag, Li, Ca, or an alloy or a compound thereof such as MgAg, MgIn, AlLi, or CaF₂, or calcium nitride may be used.

The second electrode layer 189 and the adhesion layer 193 are made in contact with each other, and then cured. Thus, a light-emitting element 190 including the first electrode layer 185, the adhesion layer 193, the electroluminescent layer 188, and the second electrode layer 189 is formed (see FIG. 7B).

In the display device of this embodiment mode shown in FIGS. 7A and 7B, light emitted from the light-emitting element 190 is transmitted and emitted from the first electrode layer 185 side to a direction indicated by an arrow in FIG. 7B.

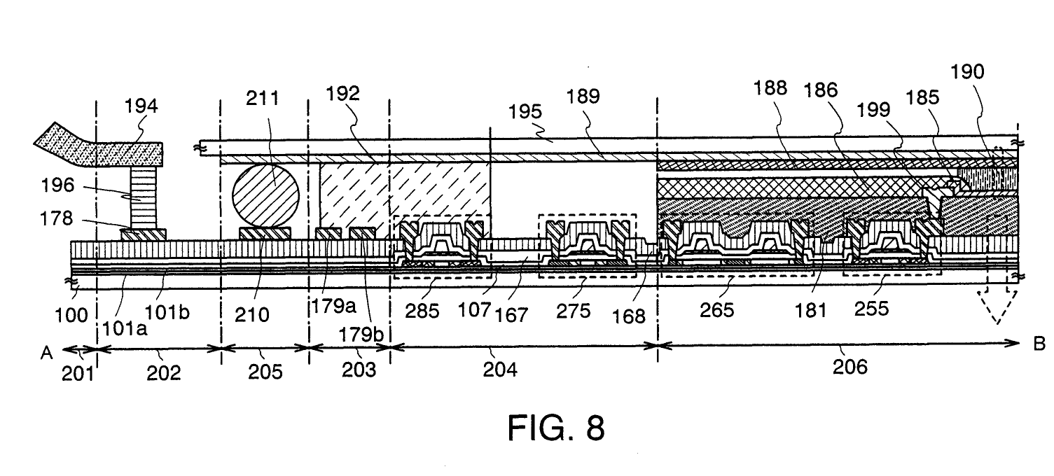

FIG. 8 shows an example to connect the source electrode layer or drain electrode layer to the first electrode layer through a wiring layer so as to be electrically connected instead of direct contact. In the display device shown in FIG. 8, the source electrode layer or drain electrode layer of the thin film transistor which drives the light-emitting element and a first electrode layer 185 are electrically connected through a wiring layer 199. Moreover, in FIG. 8, the first electrode layer 185 is partially stacked over the wiring layer 199; however, the first electrode layer 185 may be formed first and then the wiring layer 199 may be formed over the first electrode layer 185.

In this embodiment mode, an FPC 194 is connected to the terminal electrode layer 178 by an anisotropic conductive layer 196 at the external terminal connection region 202 so as to have an electrical connection with outside. Moreover, as shown in FIG. 7A which is a top view of the display device, the display device manufactured in this embodiment mode includes a peripheral driver circuit region 207 and a peripheral driver circuit region 208 each having a scanning line driver circuit in addition to the peripheral driver circuit region 204, and a peripheral driver circuit region 209 each having a signal line driver circuit.

In this embodiment mode, the aforementioned circuits are used; however, the present invention is not limited to this and an IC chip may be mounted as a peripheral driver circuit by a COG method or a TAB method. Moreover, a gate line driver circuit and a source line driver circuit may be provided in any number.

Moreover, a driving method to display an image is not particularly limited in a display device of the present invention. For example, a dot sequential driving method, a line sequential driving method, an area sequential driving method, or the like is preferably used. Representatively, a line sequential driving method is used in combination with a time division grayscale driving method or an area grayscale driving method appropriately. Further, a video signal inputted to the source line of the display device may be an analog signal or a digital signal. A driver circuit or the like is to be designed appropriately in accordance with the video signal.

With the use of this embodiment, the first substrate and the second substrate can be manufactured through different processes. Accordingly, manufacturing conditions of a film manufactured over each substrate can be optimized, and a high-quality display device can be manufactured.

Further, the adhesion resin can also have a function of a dielectric layer by being mixed with a high dielectric material. Accordingly, the number of film formation processes by vacuum evaporation can be reduced, leading to simplification of a process.

### Embodiment Mode 7

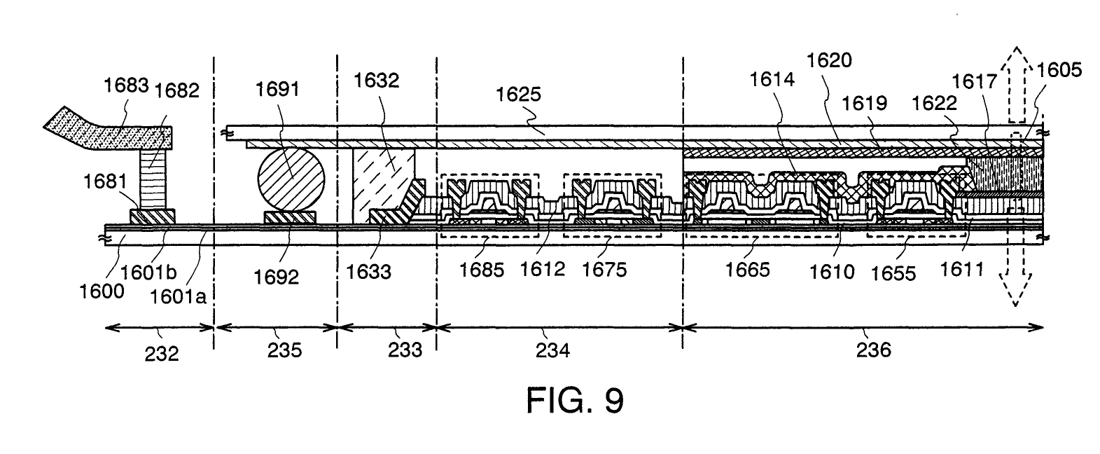

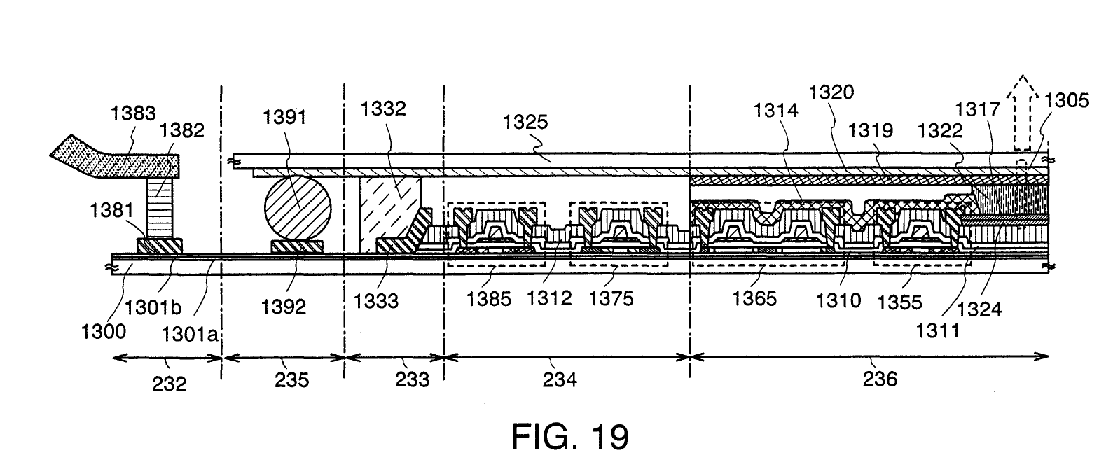

A display device having a light-emitting element can be fonned by the present invention. The light from the light-emitting element is emitted in any manner of bottom emission, top emission, and dual emission. In this embodiment mode, a dual emission type and a top emission type are described with reference to FIGS. 9 and 19. This embodiment mode shows an example in which a second interlayer insulating layer (insulating layer 181) is not formed in a display device manufactured in Embodiment Mode 5. Therefore, explanation on the same portions or portions having similar functions will not be repeated.

The display device shown in FIG. 9 includes a first substrate 1600, a thin film transistor 1655, a thin film transistor 1665, a thin film transistor 1675, a thin film transistor 1685, a first electrode layer 1617, an adhesion layer 1622, an electroluminescent layer 1619, a second electrode layer 1620, a sealing material 1632, an insulating film 1601a, an insulating film 1601b, a gate insulating layer 1610, an insulating film 1611, an insulating film 1612, an insulating layer 1614, a second substrate 1625, a connection wiring layer 1692, a conductive filler 1691, a wiring layer 1633, a terminal electrode layer 1681, an anisotropic conductive layer 1682, and an FPC 1683. The display device has an external terminal connection region 232, a connection region 235, a sealing region 233, a peripheral driver circuit region 234, and a pixel region 236.

The display device shown in FIG. 9 is a dual emission type which emits light in directions of arrows through the first substrate 1600 side and the second substrate 1625 side as well. Therefore, light-transmitting electrode layers are used for the first electrode layer 1617 and the second electrode layer 1620.

In this embodiment mode, the first electrode layer 1617 and the second electrode layer 1620 are preferably formed of light-transmitting conductive films formed of a conductive material having light-transmitting in specific, such as indium oxide containing tungsten oxide, indium zinc oxide containing tungsten oxide, indium oxide containing titanium oxide, and indium tin oxide containing titanium oxide. It is needless to say that indium tin oxide (ITO), indium zinc oxide (IZO), indium tin oxide to which silicon oxide is added (ITSO), and the like can also be used.

Further, when a material such as a metal film having no light-transmitting property is formed thin (preferably a thickness of about 5 to 30 nm) so as to be able to transmit light, light can be emitted through the first electrode layer 1617 and the second electrode layer 1620. As a metal thin film which can be used for the first electrode layer 1617 and the second electrode layer 1620, a conductive film formed of titanium, tungsten, nickel, gold, platinum, silver, aluminum, magnesium, calcium, lithium, or an alloy thereof, or the like can be used.

As described above, in the display device shown in FIG. 9, light emitted from a light-emitting element 1605 passes through both the first electrode layer 1617 and the second electrode layer 1620 and is emitted from both surfaces.

The display device shown in FIG. 19 has a top emission structure in which light is emitted in a direction of an arrow. The display device shown in FIG. 19 includes an first substrate 1300, a thin film transistor 1355, a thin film transistor 1365, a thin film transistor 1375, a thin film transistor 1385, a wiring layer 1324, a first electrode layer 1317, an electroluminescent layer 1319, an adhesion layer 1322, a second electrode layer 1320, a sealing material 1332, an insulating film 1301a, an insulating film 1301b, a gate insulating layer 1310, an insulating film 1311, an insulating film 1312, an insulating film 1314, a second substrate 1325, a wiring layer 1333, a connection wiring layer 1392, a conductive filler 1391, a terminal electrode layer 1381, an anisotropic conductive layer 1382, and an FPC 1383.

In the display devices shown in FIGS. 9 and 19, an insulating layer stacked over the terminal electrode layer is removed by etching. Reliability is further improved with a structure where an insulating layer having a moisture permeable property is not provided in the periphery of the terminal electrode layer. In FIG. 19, the display device includes an external terminal connection region 232, a connection region 235, a sealing region 233, a peripheral driver circuit region 234, and a pixel region 236. In the case of the display device shown in FIG. 19, the wiring layer 1324 as a metal layer having reflectivity is formed below the first electrode layer 1317 in the dual emission type display device shown in FIG. 9. The first electrode layer 1317 as a transparent conductive film is formed over the wiring layer 1324. As the wiring layer 1324 which may have reflectivity, a conductive film formed of titanium, tungsten, nickel, gold, platinum, silver, copper, tantalum, molybdenum, aluminum, magnesium, calcium, lithium, or an alloy thereof may be used. It is preferable to use a highly reflective substance in a visible light region. In this embodiment mode, a titanium nitride film is used. Further, a conductive film may be used for the first electrode layer 1317 as well, and in that case, the wiring layer 1324 having reflectivity may not be provided.

For the first electrode layer 1317 and the second electrode layer 1320, in specific, a transparent conductive film formed of a conductive material having a light transmitting property is preferably used, such as indium oxide containing tungsten oxide, indium zinc oxide containing tungsten oxide, indium oxide containing titanium oxide, and indium tin oxide containing titanium oxide. It is needless to say that indium tin oxide (ITO), indium zinc oxide (IZO), indium tin oxide to which silicon oxide is added (ITSO), and the like can also be used.

Further, when a material such as a metal film having no light transmitting property is formed thin (preferably a thickness of about 5 to 30 nm) so as to be able to transmit light, light can be emitted through the second electrode layer 1320. As a metal thin film which can be used for the second electrode layer 1320, a conductive film formed of titanium, tungsten, nickel, gold, platinum, silver, aluminum, magnesium, calcium, lithium, or an alloy thereof, or the like can be used.

A pixel of a display device that can be formed by using a light-emitting element can be driven by a simple matrix mode or an active matrix mode. In addition, either digital driving or analog driving can be employed.

A color filter (colored layer) may be formed on the second substrate. The color filter (colored layer) can be formed by an evaporation method or a droplet discharge method. With the use of the color filter (colored layer), display with high resolution can be performed. This is because an emission spectrum with a sharp peak can be obtained by the color filter (colored layer).

Full color display can be performed by formation of a material emitting light of a single color and combination of a color filter or a color conversion layer. The color filter (colored layer) or the color conversion layer may be formed on, for example, a second substrate (a sealing substrate), and the second substrate may be attached to the substrate.

It is needless to say that display of single color emission may also be performed. For example, an area color type display device may be formed by using single color emission. The area color type is suitable for a passive matrix display portion, and can mainly display characters and symbols.

By using the present invention, the first substrate and the second substrate can be manufactured through quite different processes. Accordingly, by optimization of processes through which each structure is manufactured, a high-quality display device can be manufactured.

Further, the adhesion resin can also have a function of a dielectric layer by being mixed with a high dielectric material. Accordingly, the number of film formation processes by vacuum evaporation can be reduced, leading to simplification of a process.

### Embodiment Mode 8

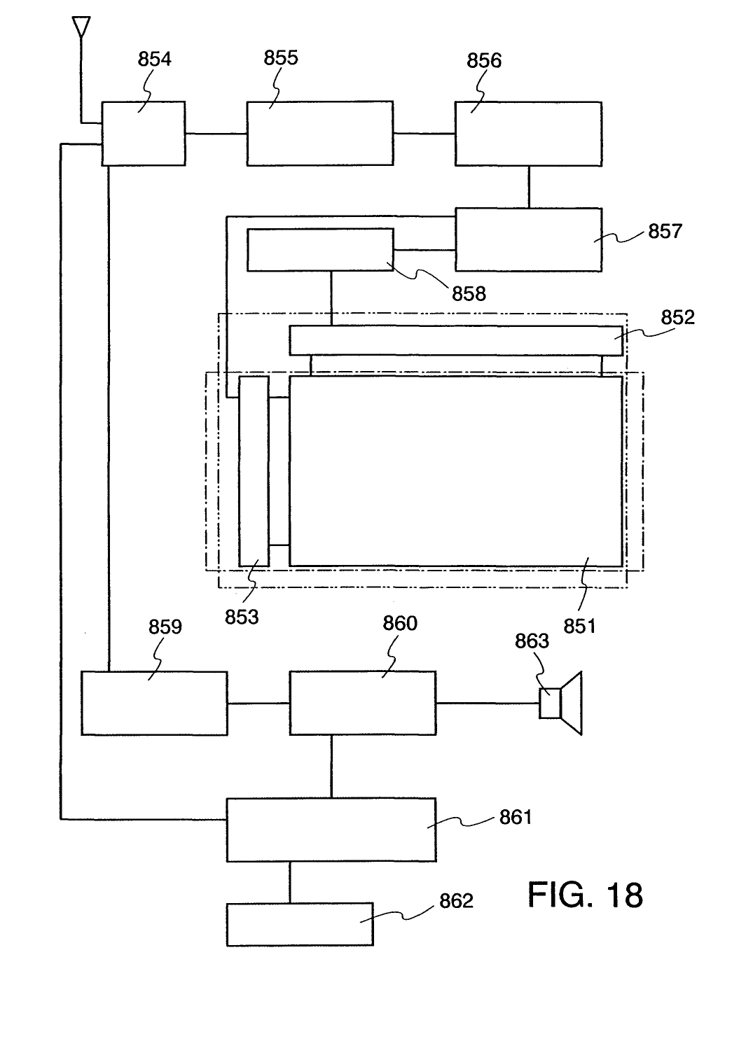

By using a display device formed by the present invention, a television device can be completed. FIG. 18 is a block diagram showing a major structure of a television device (in this embodiment mode, an EL television device). In a display panel, there are a case where only a pixel portion is formed in such a structure as shown in FIG. 16A and a scanning line driver circuit and a signal line driver circuit are mounted by a TAB method as shown in FIG. 17B, a case where they are mounted by a COG method as shown in FIG. 17A, a case where TFTs are formed of SAS as shown in FIG. 16B, the pixel portion and the scanning line driver circuit are formed over the substrate in an integrated manner, and the signal line driver circuit is mounted as a driver IC separately, and a case where the pixel portion, the signal line driver circuit, and the scanning line driver circuit are formed over the substrate in an integrated manner as shown in FIG. 16C. The display panel may have any of the aforementioned modes.

As another configuration of an external circuit, on an input side of video signals, a video signal amplifier circuit 855 which amplifies a video signal among signals received by a tuner 854, a video signal processing circuit 856 which converts a signal outputted from the video signal amplifier circuit 855 into a color signal corresponding to each color of red, green, and blue, a control circuit 857 which converts the video signal into an input specification of the driver IC, and the like are included. The control circuit 857 outputs signals to the scanning line side and the signal line side. In the case of digital driving, a signal dividing circuit 858 is provided on the signal line side so that input digital signals are divided into m pieces to be supplied.

Among the signals received by the tuner 854, audio signals are transmitted to an audio signal amplifier circuit 859 of which output is supplied to a speaker 863 through an audio signal processing circuit 860. The control circuit 861 receives control data such as a receiving station (receiving frequency) and volume from an input portion 862 and transmits signals to the tuner 854 and the audio signal processing circuit 860.

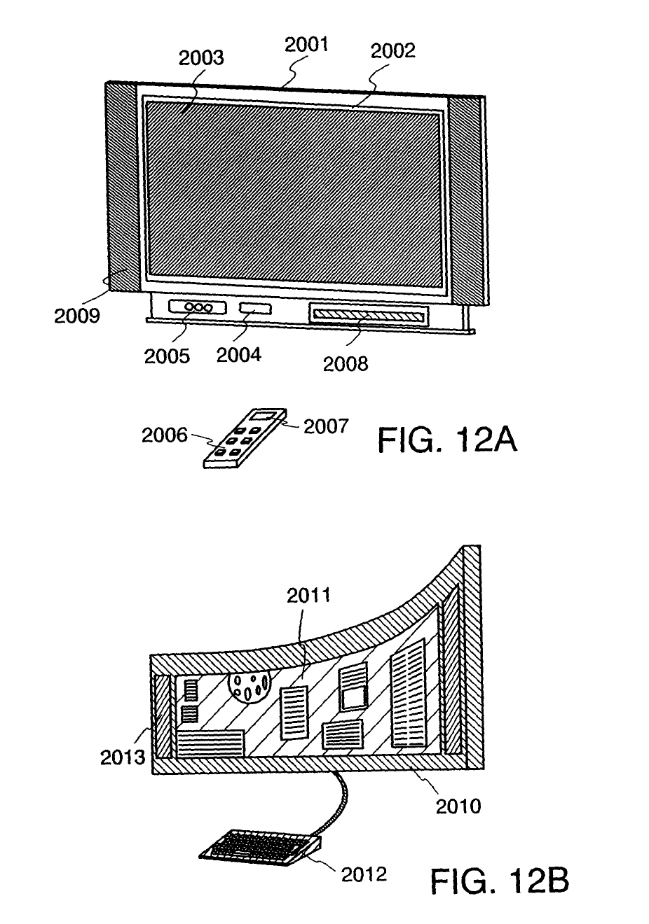

By incorporating a display module in a housing as shown in FIGS. 12A and 12B, a television device can be completed. A display panel in which components up to an FPC are set is generally also called an EL display module. Therefore, by using the EL display module, the EL television device can be completed. A main screen 2003 is formed by the display module, and as other attachment systems, a speaker portion 2009, an operating switch, and the like are provided. In this manner, a television device can be completed by the present invention.

By using a retardation film or a polarizing plate, reflected light of light incident from outside may be blocked. In the case of a top emission type display device, an insulating layer as a partition wall may be colored to be used as a black matrix. The partition wall can be formed by a droplet discharge method or the like as well, using pigment-based black resin or a resin material such as polyimide mixed with carbon black or the like, or a stack of these. A partition wall may be formed by discharging different materials in the same region a plurality of times by a droplet discharge method. As the retardation film, a quarter wave plate or a half wave plate may be used and may be designed to be able to control light. As the structure, a TFT element substrate, the light-emitting element, the sealing substrate (sealant), the retardation film (quarter wave plate), the retardation film (half wave plate), and the polarizing plate are sequentially stacked, in which light emitted from the light-emitting element is transmitted therethrough and emitted outside from the polarizing plate side. The retardation film, the polarizing plate, or the like may be stacked. The retardation film or the polarizing plate may be provided on a side where light is emitted outside or may be provided on both sides in the case of a dual emission type display device in which light is emitted from the both surfaces. In addition, an anti-reflective film may be provided outside the polarizing plate. Accordingly, an image with higher resolution and precision can be displayed.

As shown in FIG. 12A, a display panel 2002 using a display element is incorporated in a housing 2001. By connecting to a communication network in a wired or wireless manner through a modem 2004, one way (transmitter to receiver) or two-way (between transmitter and receiver or between receivers) data communication is possible as well as reception of general television broadcast by a receiver 2005. The television device can be operated by using a switch incorporated in the housing or a separate remote control operator 2006. This remote control device may be provided with a display portion 2007 which displays outputted data.

In the television device, a sub screen 2008 may be formed of a second display panel in addition to the main screen 2003, which has a structure to display a channel, volume, or the like. In this structure, the main screen 2003 may be formed of an EL display panel with a superior viewing angle while the sub screen may be formed of a liquid crystal display panel which can perform display with low power consumption. To give priority to low power consumption, the main screen 2003 may be formed of a liquid crystal display panel and the sub screen may be formed of an EL display panel so as to be capable of blinking. By using the present invention, a highly reliable display device can be manufactured even by using a large substrate with a number of TFTs and electronic components.

FIG. 12B is a television device having a large display portion in a size of, for example, 20 to 80 inches, including a housing 2010, a keyboard portion 2012 as an operating portion, a display portion 2011, a speaker portion 2013, and the like. The present invention is applied to manufacturing of the display portion 2011. The display portion shown in FIG. 12B is formed of a substance which can be curved; therefore, the television device has the curved display portion. In this manner, the shape of the display portion can be freely designed; therefore, a television device in a desired shape can be manufactured.

By using the present invention, a display device can be manufactured through simplified steps; therefore, cost can be reduced as well. As a result, a television device manufactured by the present invention can be manufactured at low cost even with a large display portion. Thus, a television device with high functionality and high reliability can be manufactured at high yield.

It is needless to say that the present invention is not limited to a television device and the present invention can be used for various applications as a large display medium such as an information display board at train stations, airports, and the like, and an advertisement board on street as well as a monitor of a personal computer.

This embodiment mode can be used by being combined with each of Embodiment Modes 1 to 7.

### Embodiment Mode 9

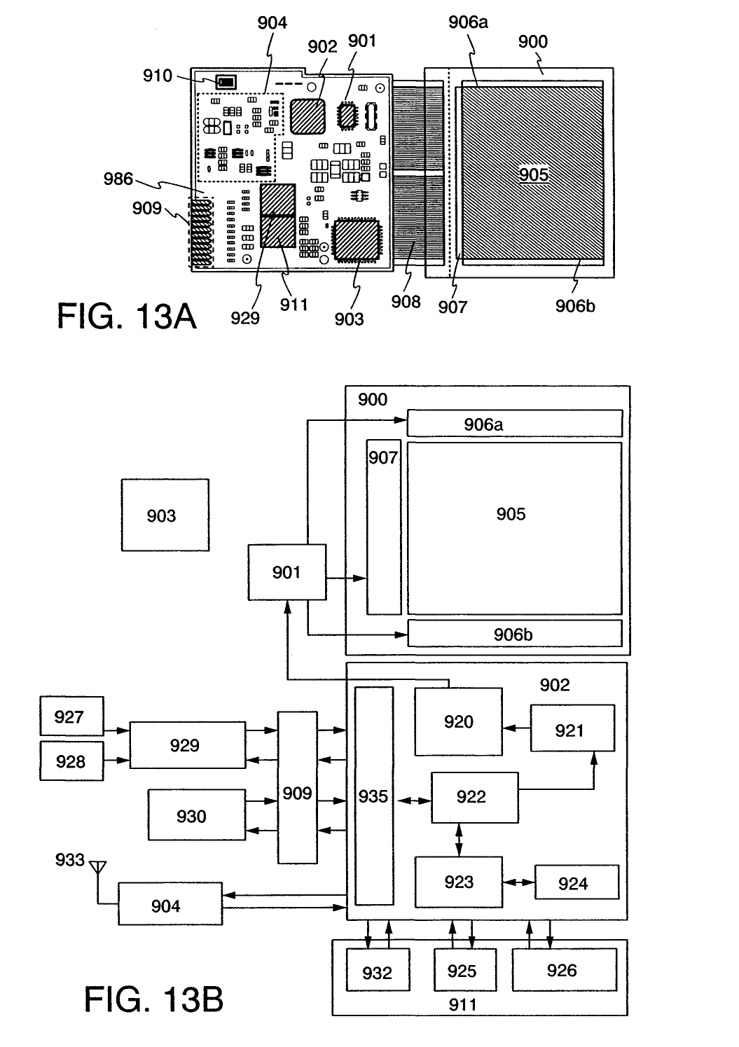

This embodiment mode is described with reference to FIGS. 13A and 13B. This embodiment mode shows an example of a module using a panel including a display device manufactured in Embodiment Modes 4 to 8.

A module of an information terminal shown in FIG. 13A includes a printed wiring board 986 over which a controller 901, a central processing unit (CPU) 902, a memory 911, a power source circuit 903, an audio processing circuit 929, a transmission/reception circuit 904, and other elements such as a resistor, a buffer, and a capacitor are mounted. In addition, a panel 900 is connected to the printed wiring board 986 through a flexible wiring circuit (FPC) 908.

The panel 900 is provided with a pixel portion 905 having a light-emitting element in each pixel, a first scanning line driver circuit 906a and a second scanning line driver circuit 906b which select a pixel included in the pixel portion 905, and a signal line driver circuit 907 which supplies a video signal to the selected pixel.

Various control signals are inputted and outputted through an interface (I/F) portion 909 provided on the printed wiring board 986. An antenna port 910 for transmitting and receiving signals to/from an antenna is provided on the printed wiring board 986.

It is to be noted in this embodiment mode that the printed wiring board 986 is connected to the panel 900 through the FPC 908; however, the present invention is not limited to this structure. The controller 901, the audio processing circuit 929, the memory 911, the CPU 902, or the power source circuit 903 may be directly mounted on the panel 900 by a COG (Chip on Glass) method. Moreover, various elements such as a capacitor element and a buffer provided on the printed wiring board 986 prevent a noise in a power source voltage or a signal and a rounded rise of a signal.

FIG. 13B is a block diagram of the module shown in FIG. 13A. This module includes a VRAM 932, a DRAM 925, a flash memory 926, and the like as the memory 911. The VRAM 932 stores image data displayed by a panel, the DRAM 925 stores image data or audio data, and the flash memory stores various programs.

The power source circuit 903 generates a power source voltage applied to the panel 900, the controller 901, the CPU 902, the audio processing circuit 929, the memory 911, and the transmission/reception circuit 904. Moreover, depending on the specifications of the panel, a current source is provided in the power source circuit 903 in some cases.

The CPU 902 includes a control signal generating circuit 920, a decoder 921, a register 922, an arithmetic circuit 923, a RAM 924, an interface 935 for the CPU, and the like. Various signals inputted to the CPU 902 through the interface 935 are inputted to the arithmetic circuit 923, the decoder 921, and the like after being held in the register 922 once. The arithmetic circuit 923 operates based on the inputted signal and specifies an address to send various instructions. On the other hand, a signal inputted to the decoder 921 is decoded and inputted to the control signal generating circuit 920. The control signal generating circuit 920 generates a signal containing various instructions based on the inputted signal and sends it to the address specified by the arithmetic circuit 923, which are specifically the memory 911, the transmission/reception circuit 904, the audio processing circuit 929, the controller 901, and the like.

The memory 911, the transmission/reception circuit 904, the audio processing circuit 929, and the controller 901 operate in accordance with respective transmitted instructions. The operations are briefly described below.

The signal inputted from an input unit 930 is transmitted to the CPU 902 mounted on the printed wiring board 986 through the interface 909. The control signal generating circuit 920 converts the image data stored in the VRAM 932 into a predetermined format in accordance with the signal transmitted from the input unit 930 such as a pointing device and a keyboard, and then transmits it to the controller 901.

The controller 901 processes a signal containing image data transmitted from the CPU 902 in accordance with the specifications of the panel and supplies it to the panel 900. The controller 901 generates and sends a Hsync signal, a Vsync signal, a clock signal CLK, an alternating voltage (AC Cont), and a switching signal L/R to the panel 900 based on the power source voltage inputted from the power source circuit 903 and various signals inputted from the CPU 902.

In the transmission/reception circuit 904, a signal transmitted and received as an electric wave by the antenna 933 is processed. In specific, high frequency circuits such as an isolator, a band path filter, a VCO (Voltage Controlled Oscillator), an LPF (Low Pass Filter), coupler, and balan are included. Among the signals transmitted and received by the transmission/reception circuit 904, signals containing audio data are transmitted to an audio processing circuit 929 in accordance with an instruction transmitted from the CPU 902.

The signals containing audio data transmitted in accordance with the instruction from the CPU 902 are demodulated into audio signals in the audio processing circuit 929 and transmitted to a speaker 928. The audio signal transmitted from a microphone 927 is modulated in the audio processing circuit 929 and transmitted to the transmission/reception circuit 904 in accordance with the instruction from the CPU 902.

The controller 901, the CPU 902, the power source circuit 903, the audio processing circuit 929, and the memory 911 can be incorporated as a package of this embodiment mode. This embodiment mode is applicable to any circuit besides high frequency circuits such as an isolator, a band path filter, a VCO (Voltage Controlled Oscillator), an LPF (Low Pass Filter), coupler, and balan.

### Embodiment Mode 10

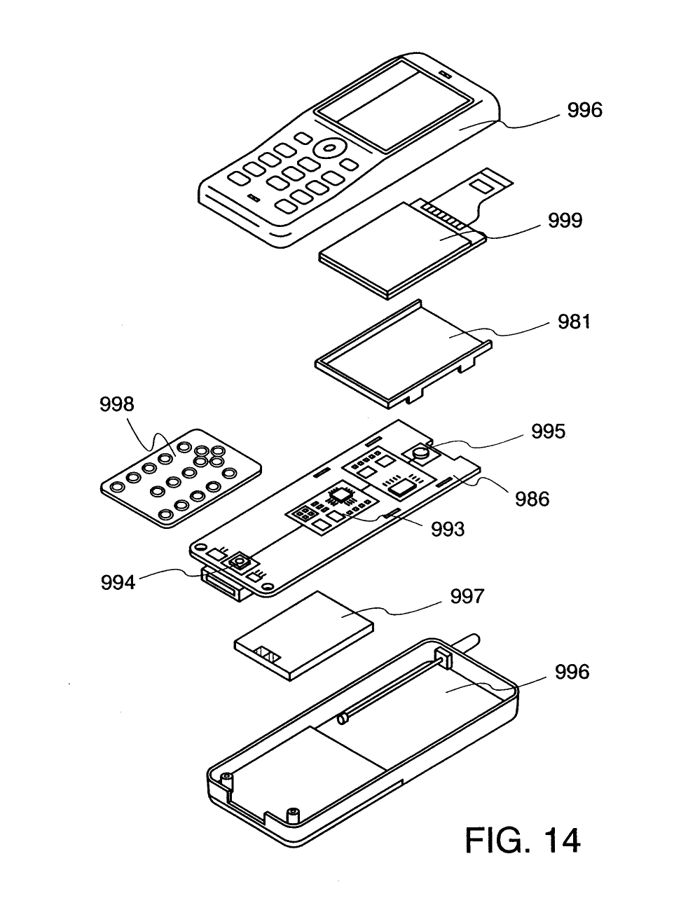

This embodiment mode is described with reference to FIG. 14. FIG. 14 shows one mode of a portable phone (mobile phone) including the module manufactured in Embodiment Mode 9, which operates wirelessly and is portable. The panel 900 is detachably incorporated in a housing 981 so as to be easily combined with a module 999. The housing 981 can be appropriately changed in shape and size in accordance with an electronic device incorporated therein.

The housing 981 in which the panel 900 is fixed is fit in the printed wiring board 986 and set up as a module. A plurality of semiconductor devices which are packaged are incorporated in the printed wiring board 986. The plurality of semiconductor devices incorporated in the printed wiring board 986 have any function of a controller, a central processing unit (CPU), a memory, a power source circuit, a resistor, a buffer, a capacitor element, and the like. Moreover, an audio processing circuit including a microphone 994 and a speaker 995 and a signal processing circuit 993 such as a transmission/reception circuit are provided. The panel 900 is connected to the printed wiring board 986 through the FPC 908.

The module 999, the housing 981, the printed wiring board 986, an input unit 998, and a battery 997 are stored in a housing 996. The pixel portion of the panel 900 is arranged so that it can be seen through a window formed in the housing 996.

The housing 996 shown in FIG. 14 shows an exterior shape of a phone as an example. However, an electronic device of this embodiment mode could change to have various aspects in accordance with functions and applications. In the following embodiment mode, an example of the modes is described.

### Embodiment Mode 11

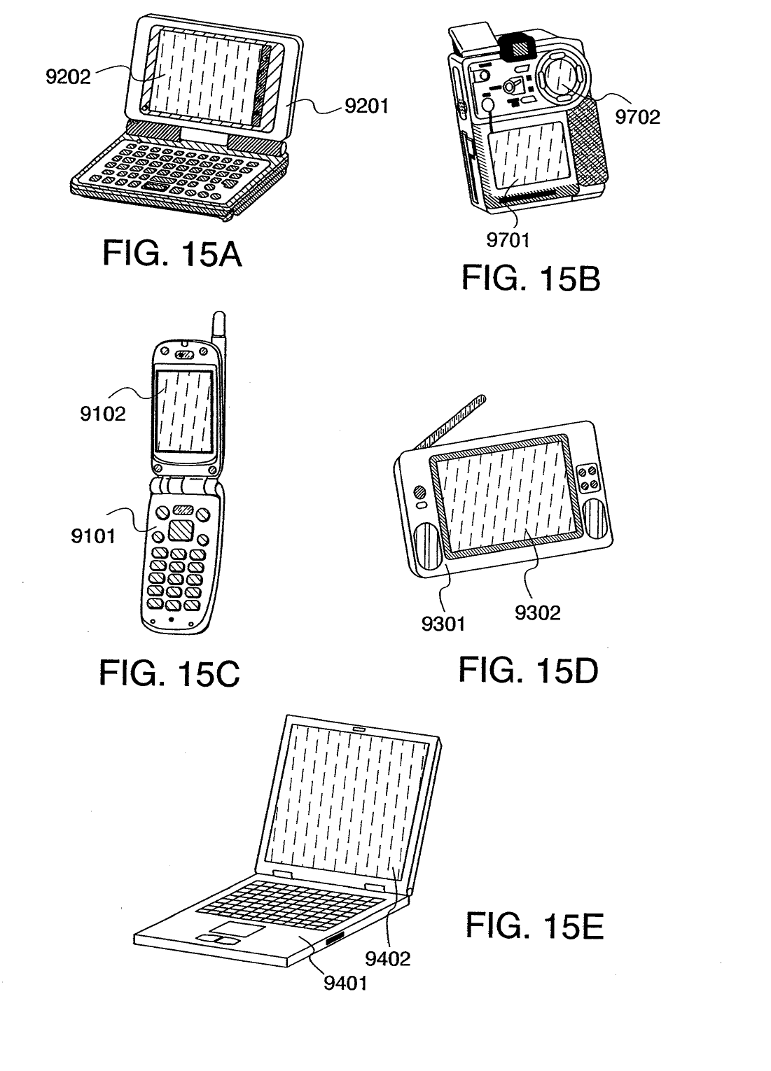

An electronic appliance of the present invention includes: a television device (also simply referred to as a TV or a television receiver), a camera such as a digital camera and a digital video camera, a mobile phone set (also simply referred to as a cellular phone set or a cellular phone), a portable information terminal such as a PDA, a portable game machine, a monitor for a computer, a computer, an audio reproducing device such as a car audio set, an image reproducing device provided with a recording medium such as a home-use game machine, and the like. Specific examples thereof will be explained with reference to FIGS. 15A to 15E.

A portable information terminal shown in FIG. 15A includes a main body 9201, a display portion 9202, and the like. The display device of the present invention is applicable to the display portion 9202. Thus, a portable information terminal with high image quality and high reliability which consumes low power can be provided.

A digital video camera shown in FIG. 15B includes a display portion 9701, a display portion 9702, and the like. The display device of the present invention is applicable to the display portion 9701. Thus, a digital video camera with high image quality and high reliability which consumes low power be provided.

A cellular phone set shown in FIG. 15C includes a main body 9101, a display portion 9102, and the like. The display device of the present invention is applicable to the display portion 9102. Thus, a cellular phone set with high image quality and high reliability which consumes low power can be provided.

A portable television set shown in FIG. 15D includes a main body 9301, a display portion 9302, and the like. The display device of the present invention is applicable to the display portion 9302. Thus, a portable television set with high image quality and high reliability which consumes low power can be provided. The display device of the present invention is applicable to various types of television sets including a small-sized television mounted on a portable terminal such as a cellular phone set, a medium-sized television that is portable, and a large-sized television (for example, 40 inches in size or more).

A portable computer shown in FIG. 15E includes a main body 9401, a display portion 9402, and the like. The display device of the present invention is applicable to the display portion 9402. Thus, a portable computer with high image quality and high reliability which consumes low power can be provided.

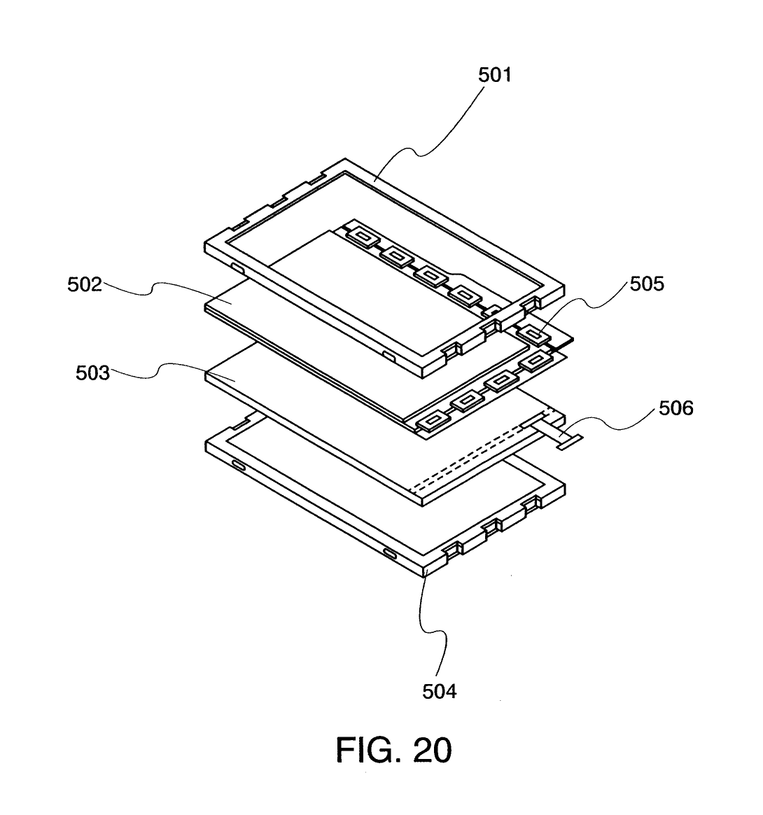

The display device of the present invention can also be used as a lighting device. One mode using the light-emitting element of the present invention as the lighting device will be explained with reference to FIG. 20.

FIG. 20 shows an example of a liquid crystal display device using the display device of the present invention as a backlight. The liquid crystal display device shown in FIG. 20 includes a chassis 501, a liquid crystal layer 502, a backlight 503, and a chassis 504, and the liquid crystal layer 502 is connected to a driver IC 505. The display device of the present invention is used for the backlight 503, and a voltage is applied by a terminal 506.

By using the display device of the present invention as the backlight of the liquid crystal display device, a backlight with long life that is unique to an inorganic EL can be obtained. The display device of the present invention is a plane emission type lighting device, and can have a large area. Therefore, the backlight can have a large area, and a liquid crystal display device can also have a large area. Furthermore, the display device has a thin shape; therefore, a thin shape of a display device can also be achieved.

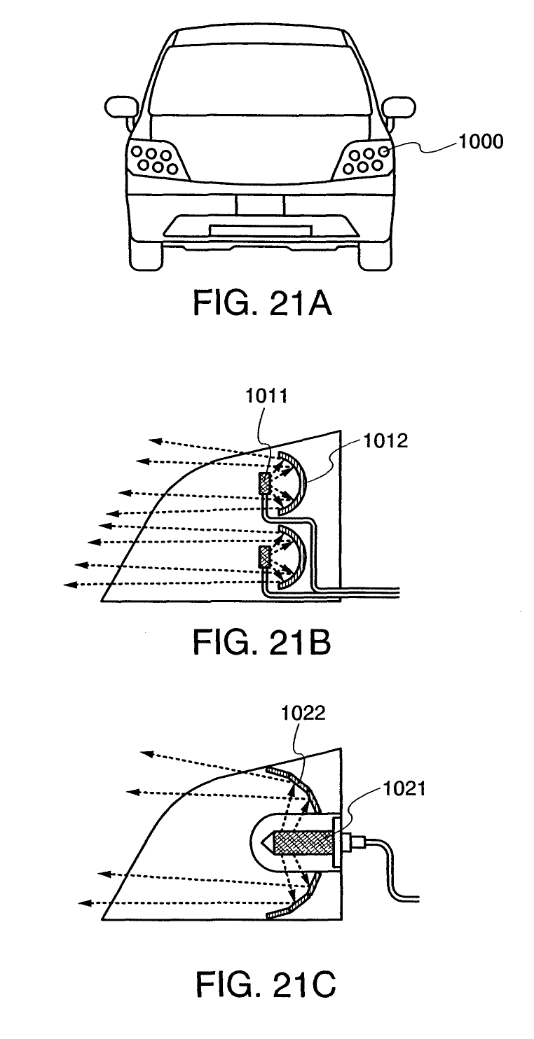

The display device of the present invention can be used as a headlight of an automobile, a bicycle, a ship, or the like. FIGS. 21A to 21C each show an example in which the display device to which the present invention is applied is used as a headlight of an automobile. FIG. 21B is a cross-sectional view in which a portion of a headlight 1000 in FIG. 21A is enlarged. In FIG. 21B, a display device of the present invention is used as a light source 1011. Light emitted from the light source 1011 is reflected by a reflecting plate 1012 to be extracted to outside. With the use of a plurality of light sources as shown in FIG. 21B, light with higher luminance can be obtained. FIG. 21C shows an example in which the display device of the present invention manufactured in a cylindrical shape is used as a light source. Light emitted from a light source 1021 is reflected by a reflecting plate 1022 to be extracted to outside.

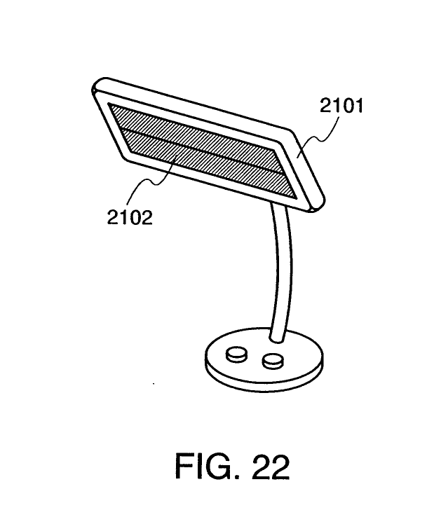

FIG. 22 shows an example in which the display device to which the present invention is applied is used as a table lamp, which is a lighting device. A table lamp shown in FIG. 22 has a chassis 2101 and a light source 2102, and the display device of the present invention is used as the light source 2002. The display of the present invention can emit light with high luminance; therefore, when detailed work is being performed, the area at hand where the work is being performed can be brightly lighted up.

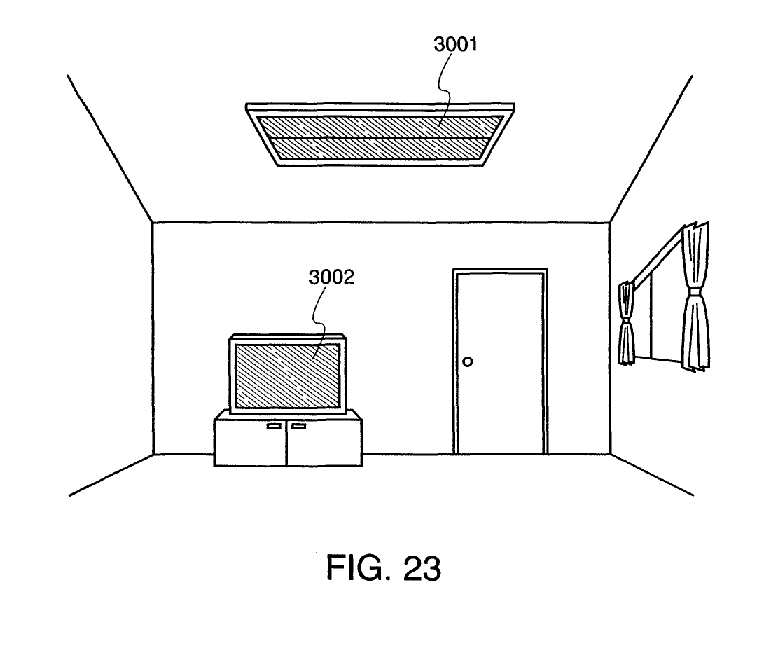

FIG. 23 shows an example in which the display device to which the present invention is applied is used as an indoor lighting device 3001. Since the display device of the present invention can have a large area, the display device of the present invention can be used as a lighting device having a large area. Further, the display device of the present invention has a thin shape and consumes low power; therefore, the display device of the present invention can be used as a lighting device having a thin shape and consuming low power. A television device of the present invention as explained in FIGS. 12A and 12B is placed in a room in which the display device to which the present invention is applied is used as the indoor lighting device 3001 in such a manner. Thus, public broadcasting and movies can be watched. In such a case, since both of the devices consume low power, a powerful image can be watched in a bright room without concern about electricity charges.

A lighting device is not limited to that illustrated in FIGS. 21A to 21C, FIG. 22, and FIG. 23, and is applicable as a lighting device with various modes such as lighting for houses or public facilities. In such a case, in the lighting device of the present invention, since a light-emitting medium having a thin film shape is used, the degree of freedom for design is high. Accordingly, variously-designed products can be provided in the market.

As described above, with the use of a display device of the present invention, an electronic device with high image quality and high reliability which consumes low power can be provided. This embodiment mode can be freely combined with the embodiment modes.

This application is based on Japanese Patent Application serial No. 2006-153564 filed in Japan Patent Office on Jun. 1, 2006, the entire contents of which are hereby incorporated by reference.

What is claimed is:

1. A manufacturing method of a light-emitting device comprising the steps of:
forming a first electrode layer over a first substrate;
forming a first dielectric layer over the first electrode layer;
forming a light-emitting layer over the first dielectric layer;
forming an adhesion layer over the light-emitting layer;
forming a second electrode layer over a second substrate, wherein the second substrate has lower heat resistance than the first substrate; and
attaching the first substrate to the second substrate to form a light-emitting element including the first electrode layer, the second electrode layer, a light-emitting layer provided therebetween.

2. The manufacturing method of a light-emitting device according to claim 1, wherein the first substrate is a quartz substrate or a ceramic substrate.

3. The manufacturing method of a light-emitting device according to claim 1, wherein the second substrate is a glass substrate.

4. The manufacturing method of a light-emitting device according to claim 1,
wherein the formation of the light emitting layer includes a step of forming a layer containing a light-emitting material and a step of heat treating the layer containing the light-emitting material.

5. The manufacturing method of a light-emitting device according to claim 1,
wherein a conductive material is mixed into the adhesion layer.

6. The manufacturing method of a light-emitting device according to claim 1,
wherein a dielectric material is mixed into the adhesion layer.

7. The manufacturing method of a light-emitting device according to claim 6,
wherein the dielectric material is a cyanoethyl cellulose-based resin, barium titanate, or strontium titanate.

8. The manufacturing method of a light-emitting device according to claim 1,
wherein the adhesion layer is formed by a dropping method.

9. A manufacturing method of a light-emitting device comprising the steps of:
forming a first electrode layer over a first substrate;
forming a first dielectric layer over the first electrode layer;
forming a light-emitting layer over the first dielectric layer;
forming an adhesion layer using an uncured resin over the light-emitting layer;
forming a second electrode layer over a second substrate, wherein the second substrate has lower heat resistance than the first substrate; and
curing the adhesion layer after the second electrode layer and the adhesion layer are made in contact with each other to form a light-emitting element.

10. The manufacturing method of a light-emitting device according to claim 9, wherein the first substrate is a quartz substrate or a ceramic substrate.

11. The manufacturing method of a light-emitting device according to claim 9, wherein the second substrate is a glass substrate.

12. The manufacturing method of a light-emitting device according to claim 9,
wherein the formation of the light emitting layer includes a step of forming a layer containing a light-emitting material and a step of heat treating the layer containing the light-emitting material.

13. The manufacturing method of a light-emitting device according to claim 9,
wherein a conductive material is mixed into the adhesion layer.

14. The manufacturing method of a light-emitting device according to claim 9,
wherein a dielectric material is mixed into the adhesion layer.

15. The manufacturing method of a light-emitting device according to claim 14,
wherein the dielectric material is a cyanoethyl cellulose-based resin, barium titanate, or strontium titanate.

16. The manufacturing method of a light-emitting device according to claim 9,
wherein the adhesion layer is formed by a dropping method.

17. The manufacturing method of a light-emitting device according to claim 9,
wherein the adhesion layer is cured by UV light.

18. A manufacturing method of a light-emitting device comprising the steps of:
forming a first electrode layer over a first substrate;
forming a first dielectric layer over the first electrode layer;
forming a light-emitting layer over the first dielectric layer;
forming a second dielectric layer over the light-emitting layer;
forming an adhesion layer using an uncured resin over the second dielectric layer;
forming a second electrode layer over a second substrate, wherein the second substrate has lower heat resistance than the first substrate; and
curing the adhesion layer after the second electrode layer and the adhesion layer are made in contact with each other to form a light-emitting element.

19. The manufacturing method of a light-emitting device according to claim 18, wherein the first substrate is a quartz substrate or a ceramic substrate.

20. The manufacturing method of a light-emitting device according to claim 18, wherein the second substrate is a glass substrate.

21. The manufacturing method of a light-emitting device according to claim 18,
wherein the formation of the light emitting layer includes a step of forming a layer containing a light-emitting material and a step of heat treating the layer containing the light-emitting material.

22. The manufacturing method of a light-emitting device according to claim 18,
wherein a conductive material is mixed into the adhesion layer.

23. The manufacturing method of a light-emitting device according to claim 18,
wherein a dielectric material is mixed into the adhesion layer.

24. The manufacturing method of a light-emitting device according to claim 23,
wherein the dielectric material is a cyanoethyl cellulose-based resin, barium titanate, or strontium titanate.

25. The manufacturing method of a light-emitting device according to claim 18,
wherein the adhesion layer is formed by a dropping method.

26. The manufacturing method of a light-emitting device according to claim 18,
wherein the adhesion layer is cured by UV light.

27. A manufacturing method of a light-emitting device comprising the steps of:
forming a first electrode layer over a first substrate;
forming an adhesion layer including an uncured resin and a light-emitting material, over the first electrode layer;
forming a second electrode layer over a second substrate, wherein the second substrate has lower heat resistance than the first substrate; and
curing the adhesion layer after the second electrode layer and the adhesion layer are made in contact with each other to form a light-emitting element.

28. The manufacturing method of a light-emitting device according to claim 27, wherein the first substrate is a quartz substrate or a ceramic substrate.

29. The manufacturing method of a light-emitting device according to claim 27, wherein the second substrate is a glass substrate.

30. The manufacturing method of a light-emitting device according to claim 27,
wherein a conductive material is mixed into the adhesion layer.

31. The manufacturing method of a light-emitting device according to claim 27,
wherein a dielectric material is mixed into the adhesion layer.

32. The manufacturing method of a light-emitting device according to claim 31,
wherein the dielectric material is a cyanoethyl cellulose-based resin, barium titanate, or strontium titanate.

33. The manufacturing method of a light-emitting device according to claim 27,
wherein the adhesion layer is formed by a dropping method.

34. The manufacturing method of a light-emitting device according to claim 27,
wherein the adhesion layer is cured by UV light.

35. A light-emitting device comprising:
a first substrate;
a first electrode layer formed over the first substrate;
a dielectric layer formed over the first electrode layer;
a light-emitting layer formed over the dielectric layer;
an adhesion layer formed over the light-emitting layer;
a second electrode layer formed over the adhesion layer; and
a second substrate formed over the second electrode layer and having lower heat resistance than the first substrate.

36. The light-emitting device according to claim 35, wherein the first substrate is a quartz substrate or a ceramic substrate.

37. The light-emitting device according to claim 35, wherein the second substrate is a glass substrate.

38. The light-emitting device according to claim 35,
wherein the light-emitting layer includes particles of a light-emitting material and a binder, and has a structure in which the particles of the light-emitting material are dispersed in the binder.

39. A light-emitting device comprising:
a first substrate;
a first electrode layer formed over the first substrate;
a dielectric layer formed over the first electrode layer;
an adhesion layer formed over the light-emitting layer and including a light-emitting material;
a second electrode layer formed over the adhesion layer;
a second substrate formed over the second electrode layer and having lower heat resistance than the first substrate.

40. The light-emitting device according to claim 39, wherein the first substrate is a quartz substrate or a ceramic substrate.

41. The light-emitting device according to claim 39, wherein the second substrate is a glass substrate.
